(19) United States
(12) Patent Application Publication
(10) Pub. No.: US 2009/0179247 A1
(43) Pub. Date: Jul. 16, 2009

(54) SEMICONDUCTOR DEVICE

(75) Inventors: Masako FUJII, Tokyo (JP); Shigeki Obayashi, Tokyo (JP); Naozumi Morino, Tokyo (JP); Atsushi Hiraiwa, Tokyo (JP); Shinichi Watarai, Tokyo (JP); Takeshi Yoshida, Tokyo (JP); Kazutoshi Oku, Tokyo (JP); Masao Sugiyama, Tokyo (JP); Yoshinori Kondo, Tokyo (JP); Yuichi Egawa, Tokyo (JP); Yoshiyuki Kaneko, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/354,254

(22) Filed: Jan. 15, 2009

(30) Foreign Application Priority Data
Jan. 16, 2008 (JP) JP2008-006436
Dec. 5, 2008 (JP) JP2008-311085

(51) Int. Cl. H01L 27/06; H01L 29/78

(52) U.S. Cl. 257/300; 257/371; 257/E27.016; 257/E29.255

(57) ABSTRACT

A technique which can improve manufacturing yield and product reliability is provided in a semiconductor device having a triple well structure. An inverter circuit which includes an n-channel type field effect transistor formed in a shallow p-type well and a p-channel type field effect transistor formed in a shallow n-type well, and does not contribute to circuit operations is provided in a deep n-type well formed in a p-type substrate; the shallow p-type well is connected to the substrate using a wiring of a first layer; and the gate electrode of the p-channel type field effect transistor and the gate electrode of the n-channel type field effect transistor are connected to the shallow n-type well using a wiring of an uppermost layer.

### CROSS-REFERENCE TO RELATED APPLICATION

The present application claims priorities from Japanese Patent Application No. JP 2008-006436 filed on Jan. 16, 2008, and Japanese Patent Application No. JP 2008-311085 filed on Dec. 5, 2008, the contents of which are hereby incorporated by reference into this application.

### TECHNICAL FIELD OF THE INVENTION

The present invention relates to a semiconductor device. More particularly, the present invention relates to a technique effectively applied to a semiconductor device having a three-layered well structure where a deep well of a second conductivity type different from a first conductivity type is provided in a substrate of the first conductivity type and a shallow well of the first conductivity type is provided in the deep well, i.e., a so-called triple well structure.

### BACKGROUND OF THE INVENTION

For example, Japanese Patent Application Laid-Open Publication No. 2006-303753 (Patent Document 1) describes a logic circuit and an I/O circuit of a semiconductor integrated circuit device having a so-called triple well structure obtained by forming a deep n-well on a p-type semiconductor substrate and forming an n-well for configuring a p-type MISFET and a p-well for configuring an n-type MISFET on the deep n-well.

In addition, Japanese Patent Application Laid-Open Publication No. 11-97560 (Patent Document 2) discloses, with respect to a non-volatile semiconductor storage device having a floating gate electrode and a control gate electrode on a semiconductor substrate, a technique for preventing reliability lowering or breakdown of an insulating film due to static charge during an etching time of a wiring layer by forming an n-well on a p-type semiconductor substrate, forming a p-well in the n-well, forming an n-type diffusion layer for preventing static charge in the p-well, and electrically connecting the diffusion layer for preventing charging and the control gate electrode.

Further, Japanese Patent Application Laid-Open Publication No. 2005-340548 (Patent Document 3) discloses a technique for preventing short-circuiting between a floating wiring and a ground wiring adjacent thereto by connecting the floating wiring to a clamp diode to let charges flowed in the floating wiring escape to the clamp diode.

Moreover, Japanese Patent Application Laid-Open Publication No. 2001-358143 (Patent Document 4) discloses a technique for providing one wiring layer including a plurality of relay pins electrically connected to a plurality of gate electrodes respectively, and an uppermost wiring layer including a plurality of wiring patterns electrically connected to the plurality of relay pins respectively; and performing wirings of the gate electrodes using the uppermost wiring pattern so that charges charged during an etching process of the wiring escape to other regions than the plurality of gate electrodes, thereby preventing deterioration of a gate insulating film.

### SUMMARY OF THE INVENTION

In a System On Chip (SOC) product, a semiconductor device having a triple well structure is used for reducing power consumption during standby or the like. In the semiconductor device having the triple well structure, however, there are various technical problems described as follows.

In general, an electrical connection between field effect transistors formed in different triple well regions and electrical connections between the field effect transistors formed on the triple well regions and a substrate are made for signal transmission and reception as necessary. However, as the inventors of the present invention have studied, it has become clear that breakdown of a gate insulating film of the field effect transistor due to the triple well structure occurs in a specific circuit. As one of effective methods for preventing such breakdown, for example, a method of making an electric connection among field effect transistors respectively formed on the different triple well regions via a level shift circuit is conceivable. However, the level shift circuit has been originally devised for connecting regions having different power source voltages, and when the level shift circuit is provided for each signal line between regions having an equal power source voltage, design becomes troublesome and the level shift circuits may occupy a partial region of the semiconductor device, which results in such a problem that the semiconductor device becomes large and a manufacturing cost of the product increases.

An object of the present invention is to provide a technique capable of improving manufacturing yield and product reliability of a semiconductor device having a triple well structure.

The above and other objects and novel features of the present invention will be apparent from the description of the present specification and the accompanying drawings.

Typical embodiments of the inventions disclosed in the present application will be briefly described as follows.

An embodiment of the present invention is a semiconductor device comprising an inverter circuit configured by: a p-type substrate; a deep n-type well which is not connected to the substrate; a shallow p-type well and a shallow n-type well formed on different regions from each other in the deep n-type well; an n-channel type field effect transistor formed on the shallow p-type well; and a p-channel type field effect transistor formed on the shallow n-type well. The shallow p-type well is connected to the substrate using a wiring of a first layer; a gate electrode of the p-channel type field effect transistor and a gate electrode of the n-channel type field effect transistor are connected to each other at the same time with formation of the gate electrodes or at an early stage of a wiring process, and they are also directly or indirectly connected to the substrate, a portion having a substrate potential, the deep n-type well, the shallow p-type well, the shallow n-type well, or a predetermined portion regarding a circuit operation by using wirings of an uppermost layer.

Another embodiment is a semiconductor device comprising an inverter circuit configured by: a p-type substrate; a deep n-type well which is not connected to the substrate; a shallow p-type well formed in a region in the substrate other than the deep n-type well; a shallow n-type well formed in the deep n-type well; an n-channel type field effect transistor formed on the shallow p-type well; and a p-channel type field effect transistor formed on the shallow n-type well. A gate electrode of the p-channel type field effect transistor and a gate electrode of the n-channel type field effect transistor are connected to each other at the same time with formation of the gate electrodes or at an early stage of a wiring process, and they are also directly or indirectly connected to the substrate, a portion having a substrate potential, the deep n-type well, the shallow p-type well, the shallow n-type well, or a predetermined portion regarding a circuit operation by using wirings of an uppermost layer.

Another embodiment is a semiconductor device comprising an inverter circuit configured by: a p-type substrate; a deep n-type well which is not connected to the substrate; a shallow n-type well formed in the deep n-type well; a shallow p-type well which is formed in a region in the deep n-type well other than the shallow n-type well and is not connected to the substrate; an n-channel type field effect transistor formed on the shallow p-type well, and a p-channel type field effect transistor formed on the shallow n-type well. A gate electrode of the p-channel type field effect transistor and a gate electrode of the n-channel type field effect transistor are connected to each other at the same time with formation of the gate electrodes or at an early stage of a wiring process, and they are also directly or indirectly connected to the substrate, a portion having a substrate potential, the deep n-type well, the shallow p-type well, the shallow n-type well, or a predetermined portion regarding a circuit operation by using wirings of an uppermost layer.

Another embodiment is a semiconductor device comprising an inverter circuit configured by: a p-type substrate; a deep n-type well; a shallow p-type well and a shallow n-type well formed in different regions from each other in the deep n-type well; an n-channel type field effect transistor formed on the shallow p-type well; and a p-channel type field effect transistor formed on the shallow n-type well. A gate electrode of the p-channel type field effect transistor and a gate electrode of the n-channel type field effect transistor are directly or indirectly connected to the substrate, a portion having a substrate potential, or a portion having a power-source potential by using wirings of an uppermost layer.

Another embodiment is a semiconductor device comprising: a p-type substrate; a deep n-type well; and a shallow p-type well and a shallow n-type well formed in different regions from each other in the deep n-type well. At least one of the deep n-type well, the shallow p-type well, and the shallow n-type well is directly or indirectly connected to the substrate or a portion having a substrate potential by using wirings of an uppermost layer.

Another embodiment is a semiconductor device comprising: a p-type substrate; a deep n-type well; and a shallow p-type well and a shallow n-type well formed in different regions from each other in the deep n-type well. At least one of a wiring connection between a portion in the shallow n-type well and the substrate, a wiring connection between the portion in the shallow n-type well and a portion in the shallow p-type well formed in a substrate region, and a wiring connection between the portion in the shallow n-type well and a portion in the shallow p-type well having a substrate potential is directly or indirectly made by using wirings of an uppermost layer.

Another embodiment is a semiconductor device comprising: a p-type substrate; a deep n-type well; and a shallow p-type well and a shallow n-type well formed in different regions from each other in the deep n-type well. The shallow p-type well is not connected to any of the substrate, the shallow well having a substrate potential, the deep n-type well, and the shallow n-type well. At least one of a wiring connection between a portion in the shallow p-type well and a portion in the shallow n-type well, a wiring connection between the portion in the shallow p-type well and a portion in the shallow n-type well formed in a substrate region, and a wiring connection between a portion in the shallow p-type well and the substrate is directly or indirectly made by using wirings of an uppermost layer.

Another embodiment is a semiconductor device comprising: a p-type substrate; a deep n-type well formed in the substrate; a shallow p-type well and a shallow n-type well formed in different regions from each other in the deep n-type well, and an n-channel type field effect transistor formed in the shallow p-type well. A drain of the n-channel type field effect transistor is connected to the shallow n-type well; the shallow p-type well is connected to a ground potential; and a gate electrode of the field effect transistor is directly or indirectly connected to the shallow n-type well, so that the field effect transistor is turned ON or OFF according to an amount of charges accumulated in the shallow n-type well.

Another embodiment is a semiconductor device comprising: a p-type substrate; a deep n-type well formed in the p-type substrate; a shallow p-type well and a shallow n-type well formed in different regions from each other in the deep n-type well; and an n-channel type field effect transistor formed in the shallow p-type well. A drain of the field effect transistor is connected to the shallow n-type well; the shallow p-type well is connected to a ground potential; and a gate electrode of the n-channel type field effect transistor is connected to a wiring put in a floating state, so that the n-channel type field effect transistor is turned ON or OFF according to an intermediate potential of the wiring put in a floating state.

The effects obtained by a typical embodiment of the present invention will be briefly described below.

With regard to a semiconductor device having a triple well structure, manufacturing yield and product reliability can be improved by preventing breakdown of a gate insulating film of a field effect transistor formed in a triple well region.

### BRIEF DESCRIPTIONS OF THE DRAWINGS

FIG. 1 is a configuration diagram of an audio and image processing apparatus used for analysis by the inventors of the present invention;

FIG. 2 is a circuit diagram showing one example of an I/O (input and output) circuit unit and a logic circuit unit configuring the audio and image processing apparatus shown in FIG. 1;

FIG. 3 is a schematic cross-sectional view of a circuit device for describing a first failure generation mechanism when positive charges are accumulated in a deep-well;

FIG. 4A is a schematic diagram for describing a flow of charges in an inverter circuit;

FIG. 4B is a schematic diagram for describing a flow of charges in the inverter circuit;

FIG. 5 is a schematic cross-sectional view of a circuit device for describing a second failure generation mechanism in the case where positive charges are accumulated in a deep-well;

FIG. 6 is a circuit diagram showing another example of an I/O (input and output) circuit unit and a logic circuit unit configuring the audio and image processing apparatus shown in FIG. 1;

FIG. 7 is a schematic cross-sectional view of a circuit device for describing a third failure generation mechanism in the case where negative charges are accumulated in a shallow well formed in a deep-well and having a same conductivity type as a substrate;

FIG. 8 is a schematic cross-sectional view of a circuit device for describing a fourth failure generation mechanism in the case where negative charges are accumulated in a shallow well formed in a deep-well and having a same conductivity type as a substrate;

FIG. 9 is a circuit diagram showing an example of an I/O (input and output) circuit unit and a logic circuit unit configuring an audio and image processing apparatus according to a first embodiment;

FIG. 10 is a cross-sectional view of main parts of a region including a pMIS and an nMIS configuring an inverter circuit to which a first method is applied according to the first embodiment;

FIG. 11 is a schematic cross-sectional view of a circuit device for describing the inverter circuit to which the first method is applied according to the first embodiment;

FIG. 12 is a schematic cross-sectional view of a circuit device for describing an MIS to which the first method is applied according to the first embodiment;

FIG. 13 is a circuit diagram showing an example of an I/O (input and output) circuit unit and a logic circuit unit configuring an audio and image processing apparatus according to a second embodiment;

FIG. 14 is a circuit diagram showing an example of an I/O (input and output) circuit unit and a logic circuit unit configuring an audio and image processing apparatus according to a third embodiment;

FIG. 15 is a cross-sectional view of main parts of a region including a pMIS and an nMIS configuring an inverter circuit to which the first method is applied according to the third embodiment;

FIG. 16 is a circuit diagram showing an example of an I/O (input and output) circuit unit and a logic circuit unit configuring an audio and image processing apparatus according to a fourth embodiment;

FIG. 17 is a circuit diagram showing an example of an I/O (input and output) circuit unit and a logic circuit unit configuring an audio and image processing apparatus according to a fifth embodiment;

FIG. 18 is a schematic cross-sectional view of a circuit device for describing an inverter circuit to which a second method is applied according to the fifth embodiment;

FIG. 19 is a schematic cross-sectional view of a circuit device for describing an MIS to which the second method is applied according to the fifth embodiment;

FIG. 20 is a circuit diagram showing an example of an I/O (input and output) circuit unit and a logic circuit unit configuring an audio and image processing apparatus according to a sixth embodiment;

FIG. 21 is a schematic cross-sectional view of a charging prevention circuit of a first example according to a seventh embodiment;

FIG. 22 is a schematic cross-sectional view of a charging prevention circuit of a second example according to the seventh embodiment;

FIG. 23A is a schematic plan view of a charging prevention circuit of a fourth example according to the seventh embodiment;

FIG. 23B is a schematic cross-sectional view of the charging prevention circuit of the fourth example according to the seventh embodiment;

FIG. 24 is a schematic cross-sectional view of a charging prevention circuit of a fifth example according to the seventh embodiment;

FIG. 25 is a schematic cross-sectional view of a charging prevention circuit of a sixth example according to the seventh embodiment;

FIG. 26A is a schematic plan view of a charging prevention circuit of a seventh example according to the seventh embodiment;

FIG. 26B is an equivalent circuit diagram of the charging prevention circuit of the seventh example according to the seventh embodiment;

FIG. 27A is a schematic plan view of a charging prevention circuit of an eighth example according to the seventh embodiment;

FIG. 27B is an equivalent circuit diagram of the charging prevention circuit of the eighth example according to the seventh embodiment;

FIG. 28A is a schematic plan view of a charging prevention circuit of a ninth example according to the seventh embodiment;

FIG. 28B is an equivalent circuit diagram of the charging prevention circuit of the ninth example according to the seventh embodiment;

FIG. 29A is another schematic plan view of a charging prevention circuit of the ninth example according to the seventh embodiment;

FIG. 29B is another equivalent circuit diagram of the charging prevention circuit of the ninth example according to the seventh embodiment;

FIG. 30A is a schematic plan view of a charging prevention circuit of a tenth example according to the seventh embodiment;

FIG. 30B is an equivalent circuit diagram of the charging prevention circuit of the tenth example according to the seventh embodiment;

FIG. 31 is a schematic cross-sectional view of a charging prevention circuit of an eleventh example according to the seventh embodiment;

FIG. 32 is a schematic cross-sectional view of a charging prevention circuit of a twelfth example according to the seventh embodiment; and

FIG. 33 is a schematic cross-sectional view of an inverter circuit for describing conduction states of a shallow n-type well and a shallow p-type well.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Also, in some drawings used in the embodiments, hatching is used even in a plan view so as to make the drawings easy to see. In the following embodiments, a metal insulator semiconductor field effect transistor (MISFET) representing a field effect transistor is abbreviated as “MIS”, a p-channel type MISFET is abbreviated as “pMIS”, and an n-channel type MISFET is abbreviated as “nMIS”. In the following embodiments, the term “wafer” mainly indicates a silicon (Si) single-crystal wafer and it indicates not only the same but also a silicon on insulator (SOI) wafer, an insulating film substrate for forming an integrated circuit thereon, or the like. The shape of the wafer includes not only a circular shape or an approximately circular shape but also a square shape, a rectangular shape, and the like.

Also, in the following embodiments, a deep-well and a shallow well are used to express wells configuring a triple well structure, and the terms “deep” and “shallow” used here indicate a depth from a main surface of a substrate in a thickness direction of the substrate, and the deep-well and the shallow well are directed to a concept obtained by roughly classifying depths to two relative depths. Accordingly, a plurality of deep-wells does not necessarily indicate the same depth but they may be wells having different depths. Similarly, a plurality of shallow wells does not necessarily indicate the same depth but they may be different depths. However, a plurality of deep-wells are necessarily formed to be deeper than a plurality of shallow wells. A shallow well may be formed in a substrate or in a deep-well, and a plurality of shallow wells may be formed in different regions from each other in a substrate which does not include a deep-well or in different regions from each other in a deep-well.

Hereinafter, embodiments of the present invention will be described in detail with reference to the accompanying drawings. Note that, components having the same function are denoted by the same reference symbols throughout the drawings for describing the embodiment, and the repetitive description thereof will be omitted.

First, since semiconductor devices according to the embodiments of the present invention will become clearer, a cause of breakdown of a gate insulating film of an MIS formed in triple well regions, which has been found by the present inventors will be described.

As the inventors of the present invention have studied, it has been found out that, when a connection hole for connecting upper layer wiring and a lower layer wiring is to be formed in an insulating film formed between the upper layer wiring and the lower layer wiring, a gate insulating film of an MIS formed in a triple well region exhibits breakdown. Since formation of the connection hole is performed by a dry etching method using plasma discharge, it is estimated that electrostatic breakdown has been caused by charging due to the plasma discharge. Further, it has been also found out that a deep-well configuring the triple well region is charged by the plasma discharge and breakdown occurs in the gate insulating film of an MIS interposed in a pass from the deep-well to a substrate. Especially, it has been found out that, when an area of the deep-well is large, the frequency of occurrence of breakdown increases. Note that, a mechanism about breakdown occurring in a gate insulating film of a field effect transistor according to charging due to plasma discharge is described in detail in K. P. Cheung, “Plasma Charging Damage in Advanced VLSI Manufacturing”, 1998 IEDM Short Course, and J. P. McVittie, “Plasma Currents, Voltages and Charging”, 1997 2nd International Symposium on Plasma Process-Induced Damage, Tutorial.

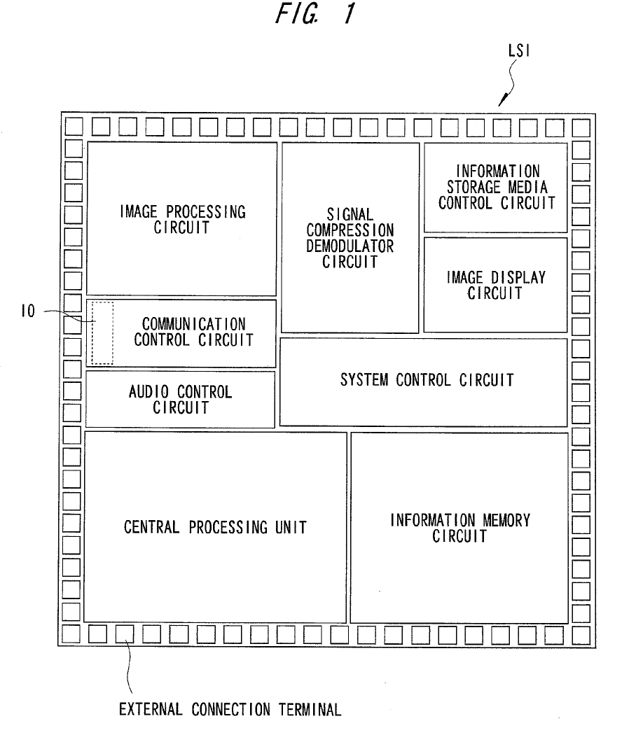

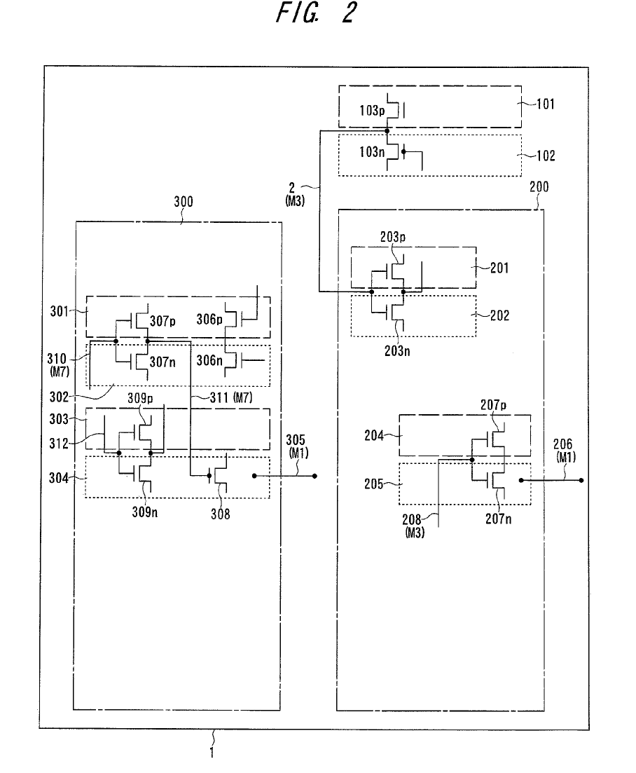

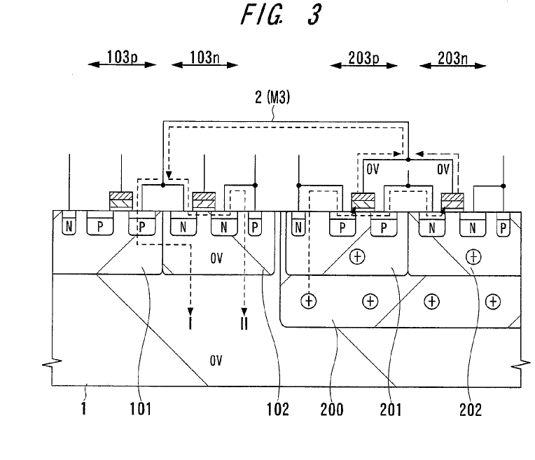

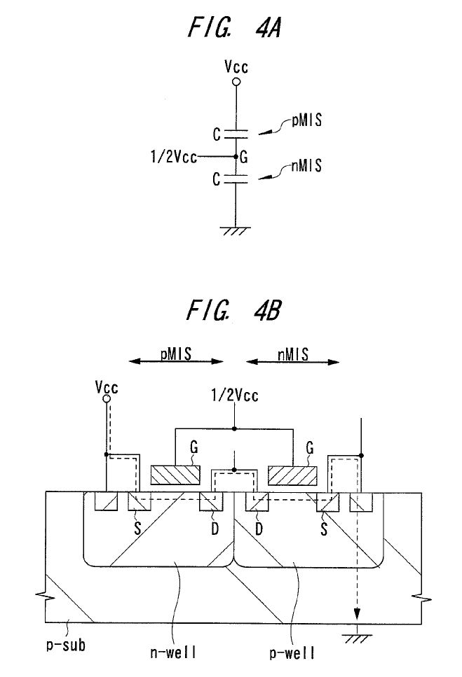

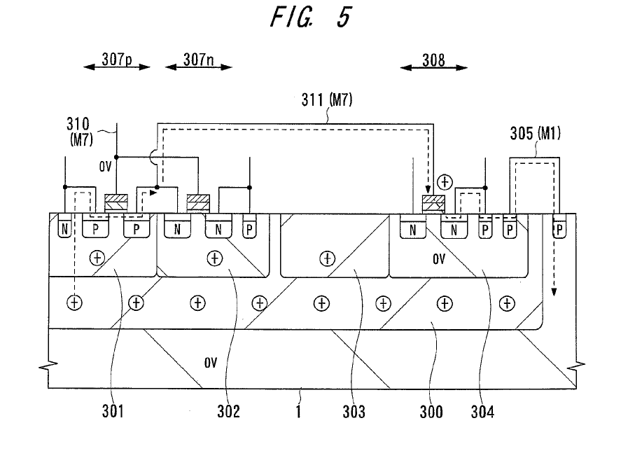

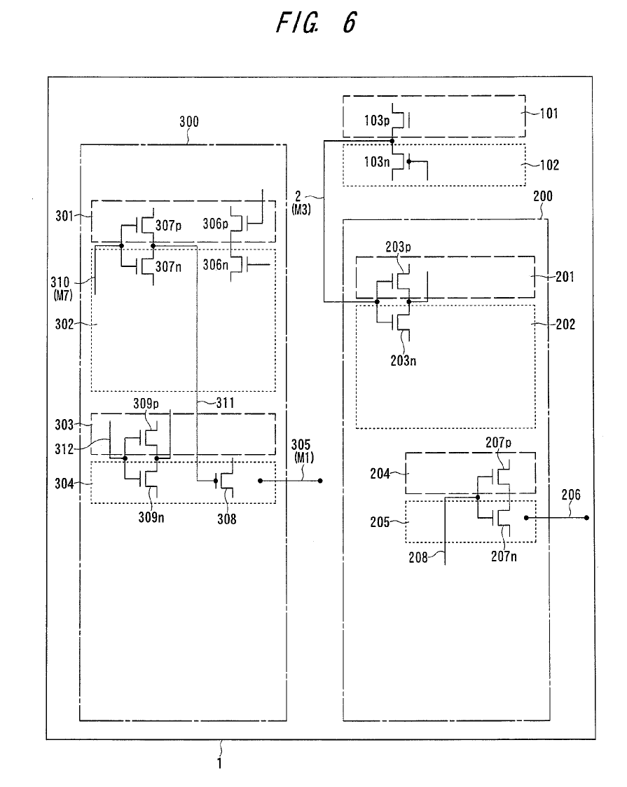

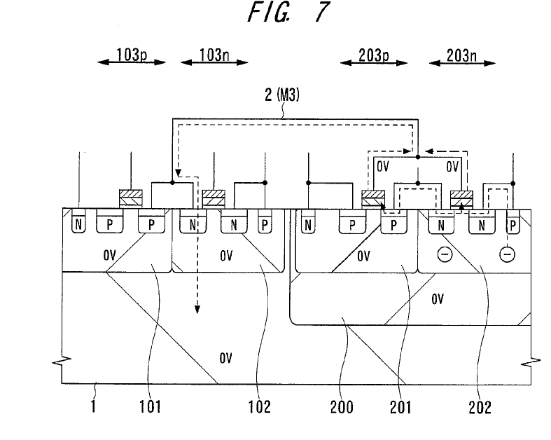

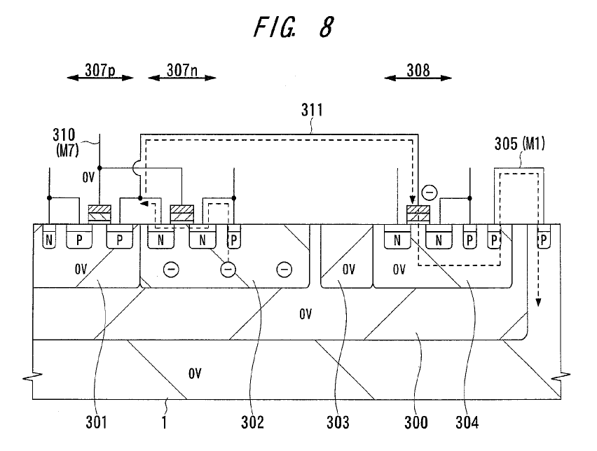

A result of an analysis on breakdown of a gate insulating film of an MIS formed in a triple well region which has been obtained by the present inventors will be described specifically with reference to FIG. 1 to FIG. 8. FIG. 1 is a configuration diagram of an audio and image processing apparatus used for analysis by the present inventors, FIG. 2 is a circuit diagram showing one example of an I/O (input and output) circuit unit and a logic circuit unit configuring the audio and image processing apparatus shown in FIG. 1, FIG. 3 is a schematic cross-sectional view of a circuit device for describing a first failure generation mechanism in the case where positive charges are accumulated in a deep-well, FIGS. 4A and 4B are schematic diagrams for describing a flow of charges in an inverter circuit, FIG. 5 is a schematic cross-sectional view of a circuit device for describing a second failure generation mechanism in the case where positive charges are accumulated in a deep-well, FIG. 6 is a circuit diagram showing another example of the I/O (input and output) circuit unit and the logic circuit unit configuring the audio and image processing apparatus shown in FIG. 1, FIG. 7 is a schematic cross-sectional view of a circuit device for describing a third failure generation mechanism in the case where negative charges are accumulated in a shallow well formed in a deep-well and having a same conductivity as a substrate, and FIG. 8 is a schematic cross-sectional view of a circuit device for describing a fourth failure generation mechanism in the case where negative charges are accumulated in a shallow well formed in a deep-well and having a same conductivity as a substrate.

As shown in FIG. 1, an audio and image processing apparatus LSI comprises a plurality of circuits including an image processing circuit, a communication control circuit, an audio control circuit, and the like, where I/O circuit units are provided in many of these circuits, so that a voltage required for circuit operation is intermittently supplied to a logic circuit unit via the I/O circuit unit as a signal. In FIG. 1, an I/O circuit unit IO provided in only the communication control circuit is exemplified and I/O circuit units provided in other circuits are omitted, but I/O circuit units are provided in many of the other circuits.

As shown in FIG. 2, in the logic circuit unit, deep n-type wells 200 and 300 are formed in different regions from each other in a p-type substrate 1. The deep n-type wells 200 and 300 are not electrically connected to the substrate 1 according to a necessity in circuit design for supplying power supply voltage. Note that, other than the deep n-type wells 200 and 300, a plurality of deep n-type wells are formed in the circuit unit, but illustrations thereof are omitted here.

As the present inventors have manufactured a semiconductor device having a triple well structure (for example, the abovementioned audio and image processing apparatus LSI) and have performed a performance test thereof, they have confirmed a first failure generation mechanism and a third failure generation mechanism where a gate insulating film of an MIS is subjected to breakdown when a gate electrode of the MIS and a drain electrode of the MIS are connected between inside and outside of a deep-well and a second failure generation mechanism and a fourth failure generation mechanism where a gate insulating film of an MIS is led to breakdown when a gate electrode of the MIS and a drain electrode of the MIS are connected inside the same deep-well. The first and second failure generation mechanisms are mechanisms due to discharge of positive charges, while the third and fourth failure generation mechanisms are mechanisms due to discharge of negative charges. The first to fourth failure generation mechanisms will be described below. The inverter circuit is a circuit comprising a set of a pMIS and an nMIS, where gate electrodes of the both are connected to each other, drains thereof are connected to each other, the source of the pMIS is connected to an n-type well in which the pMIS is formed, and a source of the nMIS is connected to a p-type well in which the nMIS is formed.

First, the first failure generation mechanism where breakdown of the gate insulating film of the MIS occurs due to positive charging when the gate electrode of the MIS and the drain electrode of the MIS are connected between the inside and the outside of the deep-well, and the second failure generation mechanism where breakdown of the gate insulating film of the MIS occurs due to positive charging when the gate electrode of the MIS and the drain electrode of the MIS are connected inside the same deep-well will be described.

I. First Failure Generation Mechanism (breakdown due to positive charging of a deep-well when a gate electrode of a MIS and a drain electrode of a MIS are connected between inside and outside of the deep-well):

As shown in FIG. 2 described above, a shallow n-type well 201 and a shallow p-type well 202 are formed in different regions from each other in the deep n-type well 200, and a pMIS 203p is formed in the shallow n-type well 201, while an nMIS 203n is formed in the shallow p-type well 202. The inverter circuit comprises the pMIS 203p and nMIS 203n. It has been confirmed by the present inventors' function examination that breakdown has occurred in the gate insulating film of the pMIS 203p or the gate insulating film of the nMIS 203n. The gate electrode of the pMIS 203p and the gate electrode of the nMIS 203n are electrically connected to a drain of a pMIS 103p and a drain of an nMIS 103n formed in a region outside the deep n-type well 200, for example, an I/O circuit unit, by using a wiring 2 (M3) of a third layer.

Further, while an inverter circuit including an nMIS 207n as a constituent component formed in a shallow p-type well 205 electrically connected to the substrate 1 by a wiring 206 (M1) of a first layer is formed in the deep n-type well 200, a gate electrode of the nMIS 207n is connected to a predetermined portion by a wiring 208 (M3) of the third layer.

Next, a mechanism where breakdown occurs in the gate insulating film of the pMIS 203p or the gate insulating film of the nMIS 203n of the inverter circuit will be described with reference to FIG. 3 and FIGS. 4A and 4B. FIG. 3 is a schematic diagram showing an aspect of the deep n-type well 200 of a semiconductor device during manufacture being charged positively by plasma discharge of a dry etching method when forming connection holes (reaching the shallow n-type well 201 and the shallow p-type well 202 via wirings of the first layer, a second layer, and the third layer) in an interlayer insulating film formed on the wiring of the third layer. When positive charges flow from the connection holes in the shallow n-type well 201 and the shallow p-type well 202 formed in the deep n-type well 200, the inflow positive charges are accumulated in the deep n-type well 200 because the deep n-type well 200 is not electrically connected to the substrate 1. On the other hand, even if positive charges flow in a shallow p-type well 102 which is not formed in the deep n-type well 200 but is formed in the substrate 1, the inflow positive charges are discharged to the substrate 1 because the shallow p-type well 102 has the same conductivity type as the substrate 1.

Meanwhile, when inverter circuits configured by a pMIS (not shown) formed in a shallow n-type well 101 and an nMIS (not shown) formed in the shallow p-type well 102 which are formed in the substrate 1 include an invert circuit where gate electrodes of the pMIS and the nMIS are mutually connected and are put in a floating state, it is conceivable that the shallow n-type well 101 and the shallow p-type well 102 formed in different regions from each other are put in a mutually conducted state having a low resistance. This phenomenon can be described in the following manner. First, as shown in FIG. 4A, when a voltage Vcc is applied to the source of the pMIS configuring the inverter circuit having the abovementioned feature, capacitors C are formed between a gate electrode G and a channel of the pMIS and between a gate electrode G and a channel of the nMIS, respectively. As a result, a voltage Vcc/2 is applied to the gate electrode G of the pMIS and the gate electrode G of the nMIS, respectively, so that the pMIS and the nMIS are turned ON. When the pMIS and the nMIS are turned ON, as shown in FIG. 4B, positive charges flow from the source “S” of the pMIS formed in the n-type well “n-well” into the drain “D”, then further flow from the drain D of the nMIS formed in the p-type well “p-well” to the source S, and then further flow to the p-type well p-well to which the nMIS is formed and the substrate p-sub.

Thus, the shallow n-type well 101 and the shallow p-type well 102 are put in a conducted state with low resistance via the inverter circuit regardless of a connection state of the gate electrode of the nMIS 103n, so that positive charges are discharged from wirings to the substrate 1 via the shallow n-type well 101 and the shallow p-type well 102 (route I in FIG. 3). Therefore, the potential of the gate electrode of the inverter circuit comprising the pMIS 203p and the nMIS 203n become equal to the potential (0V) of the substrate 1 and a voltage applied to the gate insulating film becomes large, and as a result, breakdown occurs.

Further, even if all the gate electrodes of the inverter circuits formed in the shallow n-type well 101 and the shallow p-type well 102 are connected, when a connection destination of the gate electrode of the nMIS 103n is positively charged, the nMIS 103n is put in a conducted state, so that positive charges are discharged from the wiring to the substrate 1 via the drain and source of the nMIS 103n and the shallow p-type well 102 (route II in FIG. 3). Therefore, the potential of the gate electrode of the inverter circuit comprising the pMIS 203p and the nMIS 203n becomes equal to the potential (0V) of the substrate, and the voltage applied to the gate insulating film becomes large, then as a result, breakdown occurs. However, it is considered that eventuality dominates whether or not the connection destination of the gate electrode of the nMIS 103n is charged positively, and the probability thereof depends on the circuit configuration and shapes of circuit components and so forth. Therefore, breakdown accidentally occurs in some of semiconductor devices manufactured in a large number. Note that, when an area of the deep n-type well 200 is, for example, 1 mm² or larger, an amount of charges accumulated in the deep n-type well 200 becomes large, so that breakdown occurs easily.

II. Second Failure Generation Mechanism (breakdown due to positive charging of a deep-well when a gate electrode of a MIS and a drain electrode of a MIS are connected in the same deep-well):

As shown in FIG. 2 described above, a shallow n-type well 303 and a shallow p-type well 304 are formed in different regions from each other in the deep n-type well 300, and an nMIS 308 is further formed in the shallow p-type well 304. The shallow p-type well 304 is electrically connected to the substrate 1 by a wiring 305 (M1) of the first layer from the requirement of circuit design. In the deep n-type well 300, the shallow n-type well 303 and the shallow p-type well 304 are formed in different regions, a shallow n-type well 301 and a shallow p-type well 302 are formed in different regions, a pMIS 307p is formed in the shallow n-type well 301, and an nMIS 307n is formed in the shallow p-type well 302. An inverter circuit comprises these pMIS 307p and nMIS 307n, and an output stage of the inverter circuit and a gate electrode of the nMIS 308 formed in the shallow p-type well 304 are electrically connected to each other using a wiring 311 (M7) of a seventh layer. The gate electrode of the pMIS 307p of the inverter circuit and the gate electrode of the nMIS 307n are electrically connected to an output stage of an inverter circuit comprising a pMIS 309p formed in the shallow n-type well 303 and an nMIS 309n formed in the shallow p-type well 304 by using a wiring 310 (M7) of the seventh layer (not illustrated). Like the gate electrode of the inverter circuit comprising the pMIS 309p and the nMIS 309n, all gate electrodes of the inverter circuits including an nMIS formed in the shallow p-type well 304 as a constituent component are electrically connected to predetermined portions required for circuit operation by wirings of the seventh layer or wirings 312 and the like of the lower layers.

Next, a mechanism where breakdown occurs inside a gate insulating film of the nMIS 308 connected in the same deep-well will be described with reference to FIG. 5. FIG. 5 is an schematic diagram showing an aspect where the deep n-type well 300 of a semiconductor device is charged positively during manufacturing by plasma discharge of a dry etching method when forming connection holes in an interlayer insulating film formed on a wiring of the seventh layer. In this stage, all gate electrodes of inverter circuits including an nMIS formed in the shallow p-type well 304 as a constituent component are connected to predetermined positions. Therefore, the shallow p-type well 304 configures a diode with the shallow n-type well 303 or the deep n-type well 300, where positive charges flowed in the deep n-type well 300 via the shallow p-type well 302 and the shallow n-type wells 301 and 303 are accumulated therein without being discharged. It is estimated that a connection destination of the wiring 310 (M7) has had the same potential (OV) as the substrate 1 when the deep n-type well 300 has been charged, and the pMIS 307p is made into a conducted state at this time. As a result, a connection route from the deep n-type well 300 reaching to the gate electrode of the nMIS 308 via the shallow n-type well 301, the source and drain of the pMIS 307p formed in the shallow n-type well 301 and the wiring 311 (M7) is formed. Thereby, since an inversion layer having the same potential as the substrate 1 is formed in the nMIS 308, it can be estimated that a large voltage is applied to the gate insulating film of the nMIS 308 so that breakdown has occurred.

In this case, since a potential difference is also generated in a gate insulating film of the pMIS 307p, there is a possibility that breakdown occurs in the gate insulating film, but occurrence of breakdown has not confirmed in the function examination performed by the present inventors. This is estimated that a structural defect called “weak spot” is present in a breakdown portion of the nMIS 308 but the weak spot is not present in the gate insulating film of the pMIS 307p on the contrary.

While the failure generation mechanisms (first and second failure generation mechanisms) when the deep n-type wells 200 and 300 are charged positively has been described in the foregoing, there is a product where a shallow p-type well formed in the deep n-type well 200 or 300 is charged negatively and there is such a case where it is estimated that a shallow p-type well is charged negatively so that breakdown of a gate insulating film of a MIS occurs. This has appeared especially significantly when areas of the shallow p-type wells 202 and 302 are large shown in FIG. 6.

Next, a third failure generation mechanism where breakdown of a gate insulating film of a MIS occurs when a gate electrode of the MIS and a drain electrode of a MIS are connected between inside and outside of a deep-well due to negative charging and a fourth failure generation mechanism where breakdown of a gate insulating film of a MIS occurs when a gate electrode of the MIS and a drain electrode of a MIS are connected in the same deep-well due to negative charging will be described.

III. Third Failure Generation Mechanism (breakdown due to negative charging of a deep-well when a gate electrode of MIS and a drain electrode of MIS are connected between inside of a deep-well and outside thereof):

A mechanism where breakdown occurs in a gate insulating film of the pMIS 203p or the nMIS 203n of an inverter circuit will be described with reference to FIG. 7. FIG. 7 is an schematic diagram showing an aspect where the shallow p-type well 202 formed in the deep n-type well 200 of the semiconductor device during manufacture thereof is charged negatively by plasma discharge of a dry etching method when forming a connection hole in an interlayer insulating film formed on wirings of the third layer. When negative charges flow from the connection hole to the shallow p-type well 202 formed in the deep n-type well 200, the inflow negative charges are accumulated in the shallow p-type well 202 because the shallow p-type well 202 is formed in the deep n-type well 200 not being electrically connected to the substrate 1. On the other hand, even if charges flow in the shallow p-type well 102 which is not formed in the deep n-type well 200 but is formed in the substrate 1, the inflow charges are discharged to the substrate 1 because the shallow p-type well 102 has the same conductivity type as the substrate 1. Since a direction from the drain of the nMIS 103n connected to the wiring 2 (M3) toward the shallow p-type well 102 is a forward direction for negative charges present in the wiring 2 (M3), the negative charges are discharged to the substrate 1 via the shallow p-type well 102. Therefore, the potential of the gate electrode of the inverter circuit comprising the pMIS 203p and the nMIS 203n becomes equal to the potential of substrate 1 (0V) and a voltage applied to the gate insulating film becomes large, and then as a result, breakdown occurs.

IV. Fourth Failure Generation Mechanism (breakdown due to negative charging of a deep-well when a gate electrode of a MIS and a drain electrode of a MIS are connected in the same deep-well):

A mechanism where breakdown occurs in a gate insulating film of the nMIS 308 connected in the same deep-well will be described with reference to FIG. 8. FIG. 8 is an schematic diagram showing an aspect where the shallow p-type well 302 in the deep n-type well 300 of the semiconductor device during manufacture is charged negatively by plasma discharge of a dry etching method when forming a connection hole in an interlayer insulating film formed on wirings of the seventh layer. In this stage, all gate electrodes of inverter circuits including an nMIS formed in the shallow p-type well 302 as a constituent component are connected to predetermined portions. Therefore, the shallow p-type well 302 configure a diode with the shallow n-type well 301 or the deep n-type well 300, where negative charges flowed in the shallow p-type well 302 are accumulated therein without being discharged. It is estimated that the connection destination of the wiring 310 (M7) is at the same potential as the substrate 1 when the shallow p-type well 302 has been charged, and the nMIS 307n is made into a conducted state at this time. As a result, a negative potential is applied to the gate electrode of the nMIS 308 from the shallow p-type well 302 via the source and drain of the nMIS 307n and the wiring 311. Since the shallow p-type well 304 in which the nMIS 308 is formed is electrically connected to the substrate 1 by the wiring 305 (M1) of the first layer, a potential difference occurs in the gate insulating film of the nMIS 308, and then as a result, breakdown occurs.

According to the analysis result described above, in order to prevent breakdown of a gate insulating film of a MIS, either method of (1) a first method: (1-1) charging of a deep-well is prevented (solving means for the abovementioned first and second failure generation mechanisms) or (1-2) charging of a shallow well formed in a deep-well and having the same conductivity as a substrate is prevented (solving means for the third and fourth failure generation mechanisms), or (2) a second method: cutting off a wiring route from a deep-well or a shallow well formed in the deep-well to a substrate or a portion having a substrate potential via a gate insulating film of a MIS (solving means for the abovementioned first to fourth failure generation mechanisms) is used, or these methods may be used in combination.

Next, the first method and the second method will be described in detail.

(1) First Method

(1-1) Charging Prevention of Deep-Well

A shallow well having the same conductivity type as a substrate is formed in a deep-well, the shallow well is connected to the substrate at an early stage of a series of wiring steps and also a MIS is formed in the shallow well, an inverter circuit including the gate electrode of the MIS as a constituent component is configured at an early stage of the series of wiring steps, and the gate electrode of the MIS of the inverter circuit is maintained in a floating state without being connected to another member just until the last moment to complete the wiring steps. Here, it is preferable that a wiring connecting the gate electrode of the MISes configuring the inverter circuit and the substrate or the shallow well finally is a wiring configuring one layer of the multi-layer wirings, where the number of connection holes formed in an insulating film positioned just thereabove is less than the number of connection holes formed in an insulating film positioned just above a wiring of a lower layer. If possible, it is desirable that the above wiring connection is performed using a wiring of the uppermost layer.

Note that, the wiring of the uppermost layer described in the present embodiment indicates a wiring layer which is the same layer as a wiring layer configuring a pad. The pad is a region to be connected with a conductor for external connection such as a bonding wiring or a bump electrode in a step to be performed later.

Here, an inverter circuit including a shallow well having the same conductivity type as that of a substrate and MIS formed in the same well as constituent components is fabricated in order to prevent charging, and it does not contribute to circuit operation. When the abovementioned wiring connection can be performed using a circuit configuration element, the wiring connection can be performed using the circuit configuration element. In this case, since only avoidance of occurrence of such a situation that the gate electrode of MIS becomes a floating state at a stage of completion of a product is required, the gate electrode of MIS can be connected to an arbitrary portion required for circuit configuration. Connection between the shallow well having the same conductivity type as that of the substrate and the substrate can be indirectly performed via a shallow well connected to the substrate instead of direct connection.

(1-2) Charging Prevention of a Shallow Well Formed in a Deep-Well and Having the Same Conductivity as a Substrate

When a shallow well formed in a deep-well and having the same conductivity as a substrate is connected to the substrate, charging can be prevented by performing the connection at an early state of a series of wiring steps.

When a shallow well formed in a deep-well and having the same conductivity as a substrate cannot be connected to the substrate in view of circuit configuration, the shallow well is not connected to the substrate but a MIS is formed in the shallow well, an inverter circuit including the MIS as a constituent component is configured in an early stage of a series of wiring steps, and the gate electrode of the MIS is maintained in a floating state without being connected to another member just until the last moment to complete the wiring steps. Here, it is preferable that a wiring for finally connecting the gate electrode of the MISes configuring the inverter circuit and the substrate or the shallow well is a wiring configuring one layer of the multi-layer wirings, where the number of connection holes formed in an insulating film positioned just thereabove is less than the number of connection holes formed in an insulating film positioned just above a wiring of a lower layer. If possible, it is desirable that the above wiring connection is performed using a wiring of the uppermost layer.

Also here, an inverter circuit including a shallow well having the same conductivity type as a substrate and a MIS formed in the same well as constituent components thereof is fabricated in order to prevent charging, and it does not contribute to circuit operation. When the abovementioned wiring connection can be performed using a circuit configuration components, the wiring connection can be performed using the circuit configuration element. In this case, since only avoidance of occurrence of such a situation that the gate electrode of MIS becomes a floating state at a stage of completion of a product is required, the gate electrode of MIS can be connected to an arbitrary portion required for circuit configuration.

(2) Second Method: Cutting-off of a wiring route from a deep-well or a shallow well formed in the deep-well to a substrate or a portion having a substrate potential via a gate insulating film of MIS.

At least a part of electric connections between the triple well regions and regions other than the triple well regions is made by using a wiring that configures one layer of the multi-layered wirings and also has the number of connection holes formed in an insulating film positioned just thereabove is less than the number of connection holes formed in an insulating film positioned just above a wiring of a lower layer thereof. If possible, it is desirable to make the wiring connections using a wiring of the uppermost layer.

Electric connections between different triple well regions may be performed by the abovedescribed wiring in the same manner. Especially, this method is useful when the first method is applied to one of the triple well regions while the first method is not applied to the other.

Electric connections between the inside and outside of a shallow well having the same conductivity type as the substrate and directly or indirectly connected to the substrate may be similarly performed in the same triple well region by the abovedescribed wirings.

Electric connections between the inside and outside of a shallow well having the same conductivity type as the substrate, which is not connected to the substrate, may be similarly preformed in the triple well regions by the abovedescribed wirings.

Further, at least some of electric connections among a deep n-type well and a shallow well formed in the deep n-type well that are necessary to be connected to the substrate regarding circuit design and the substrate may be similarly performed by the abovedescribed wirings.

Next, a mechanism where breakdown of a gate insulating film of MIS can be prevented by the first method and the second method will be described. Herein, while the case where the substrate is p-type will be described, the n-type can be interpreted to p-type in the following descriptions in the case where the substrate is n-type.

(1) First Method

(1-1) Charging Prevention of Deep-Well

When gate electrodes of a pMIS and an nMIS configuring an inverter circuit formed in a targeted deep n-type well are put in a floating state, a shallow n-type well in which the pMIS is formed and a shallow p-type well in which the nMIS is formed are put in a conducted state (see FIGS. 4A and 4B). Thus, when the shallow p-type well having the same conductivity type as the p-type substrate is connected to the substrate, charges which have flowed into not only the shallow p-type well but also the deep n-type well having the shallow p-type well included therein and a shallow n-type well existing in the deep n-type well are discharged to the substrate. Accordingly, when the shallow p-type well and the substrate are connected by the first wiring layer, charging of the deep n-type well is suppressed as long as the gate electrodes of the nMIS and the pMIS configuring the inverter are in a floating state, and thus, as a result, breakdown of the gate insulating film is also prevented.

It is possible to connect the gate electrode of the pMIS and the gate electrode of the nMIS configuring the inverter circuit by utilizing the gate electrodes themselves as wirings in a formation time of the gate electrodes, and in this case, a wiring connection by a wiring step is not required to be performed.

When the gate electrodes of the pMIS and nMIS configuring the inverter circuit are in a floating state after completion of the product, a pair of corresponding shallow n-type well and shallow p-type well are changed into a conducted state, which results in an increase of power consumption, and thus it is undesirable. Therefore, the gate electrodes of the pMIS and nMIS configuring the inverter circuit which are in a floating state are connected to predetermined elements at either step of a plurality of wiring steps. However, the charging suppression effect is damaged at the moment the connection is made, and it is thus desirable to perform the connection at a later step to the utmost extent. At this time, a more excellent effect can be obtained by considering the following points.

It is considered that, when connection holes are formed in an interlayer insulating film, many of positive charges accumulated in a deep n-type well will flow in from many connection holes formed to reach a shallow p-type well and a shallow n-type well. These connection holes are formed at substantially same positions for every formation of respective interlayer insulating films so that respective wiring layers are electrically connected to a shallow p-type well or a shallow n-type well with low resistance. However, since connection portions to the outside of the semiconductor device are mainly opened in an insulating film formed on a wiring of an uppermost layer, connection holes to a shallow p-type well or a shallow n-type well are hardly formed. Therefore, even if an inverter circuit having gate electrodes of pMIS and nMIS which are in a floating state is absent, the deep n-type well is hardly charged. Accordingly, it is preferable that connections between gate electrodes of the pMIS and nMIS configuring the abovedescribed inverter circuit and predetermined portions are performed using wirings in the uppermost layer. However, even if the effect gets to be slightly decreased, the gate electrodes of the pMIS and nMIS configuring the inverter circuit may be connected to the predetermined portions by wirings formed before the wirings of the uppermost layer, if necessary. Especially, in the case of a wiring which is formed before a wiring of the uppermost layer and also has the number of connection holes formed thereon being less than the number of connection holes formed in another wiring included in a lower layer positioned below, an effect close to the case where the connection is performed using the wiring of the uppermost layer can be obtained by connecting the gate electrodes of the pMIS and nMIS configuring the inverter circuit to the predetermined portion by the wiring.

(1-2) Charging Prevention of a Shallow-Well Formed in a Deep-Well and Having the Same Conductivity as a Substrate.

When the p-type well in the deep n-type well is connected to the p-type substrate, charges are discharged without taking a special countermeasure, and so this is not problematic. However, when the shallow p-type well is not connected to the p-type substrate, the inverter circuit including an nMIS formed in the shallow p-type well as a constituent component is configured at an early stage of wiring steps, and also gate electrodes thereof are kept in a floating state. Thereby, since a set of the shallow n-type well and the shallow p-type well configuring the inverter circuit are put in a conducted state like the abovementioned item (1-1) Countermeasure of Charging Prevention of a Deep-well, negative charges which have flowed into the shallow p-type well are discharged into the substrate via the shallow n-type well and the deep n-type well.

While it is assumed to use some of elements configuring the inverter circuit here, another inverter circuit for only preventing charging of a deep n-type well or a shallow p-type well in the deep n-type well without using circuit constituent components may be formed separately. At this time, a shallow n-type well and a shallow p-type well configuring the inverter circuit may be formed separately from the other circuit devices. In either case, when gate electrodes of MISes are in a floating state at a completion time of a semiconductor device, it is undesirable that a large current flows between the shallow n-type well and the shallow p-type well at a use time of the semiconductor device so that power consumption becomes large. Therefore, it is desirable that the gate electrode is connected to a proper position, for example, the shallow p-type well, the shallow n-type well, or the substrate like the case that the inverter circuit is a circuit constituent component. When the gate electrode is connected to the shallow p-type well, the shallow n-type well, or the substrate, the gate potential is fixed, and so a transient current does not flow and increase of power consumption is small. In addition, while the gate electrode can be connected to a position other than the shallow p-type well, the shallow n-type well, and the substrate, a potential of the gate electrode fluctuates according to a circuit operation so that a transient current flows, and so the power consumption increases slightly. Note that, a method for forming a dedicated inverter circuit for the charging prevention of the deep n-type well or the shallow p-type well requires an area for forming the inverter circuit, which results in such a drawback that the semiconductor chip becomes large. On the other hand, there is such an advantage that a limitation is not made in layout, and especially when the shallow n-type well and the shallow p-type well are made dedicated ones, this advantage is enhanced. Therefore, to make the inverter circuit dedicated or not can be determined according to necessity.

(2) Second Method: Cutting-off of a wiring route from a deep-well or a shallow well formed in the deep-well and having the same conductivity as that of a substrate to the substrate or a portion having a substrate potential via a gate insulating film of MIS.

The second method aims to prevent breakdown of the gate insulating film of MIS by cutting off a current route from the deep n-type well to the substrate or a portion having a substrate potential via the gate insulating film of MIS, or a current route from the shallow p-type well in the deep n-type well to the substrate or the portion having a substrate potential via the gate insulating film of MIS during a manufacturing process where charging is significant. When many connection holes reaching the shallow p-type well or the shallow n-type well are formed, charging of the deep n-type well or the shallow p-type well formed in the deep n-type well is significant. Therefore, by connecting the deep n-type well and the substrate or a portion having a substrate potential, or by connecting the shallow p-type well formed in the deep n-type well and the substrate or the portion having a substrate potential by using a wiring layer where the number of connection holes formed in an insulating film positioned just thereabove is relatively small, a charge amount of the deep n-type well or a charge amount of the shallow p-type well in the deep n-type well after connection is reduced, thereby preventing breakdown of the gate insulating film of MIS. At this time, excellent effects can be obtained by using wirings in the uppermost layer as the abovedescribed first method.

### First Embodiment

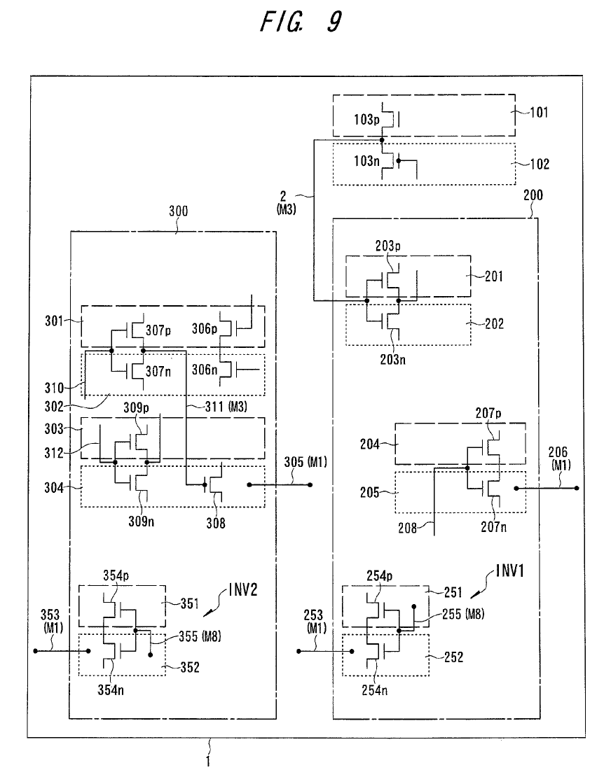

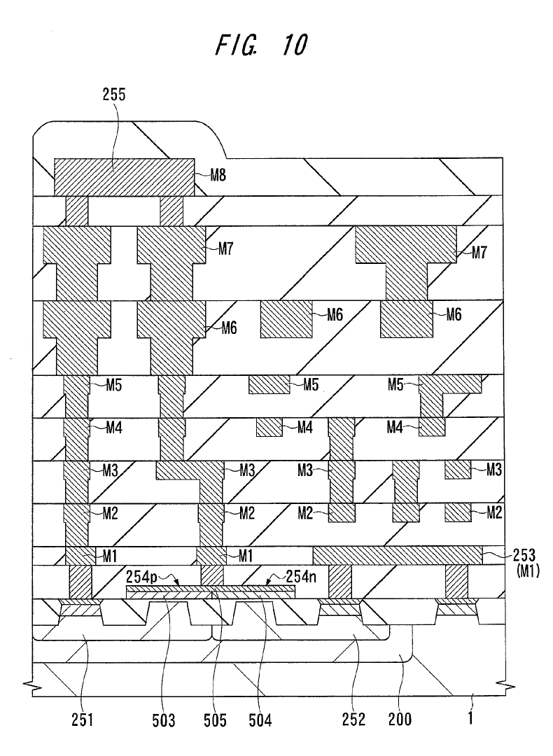

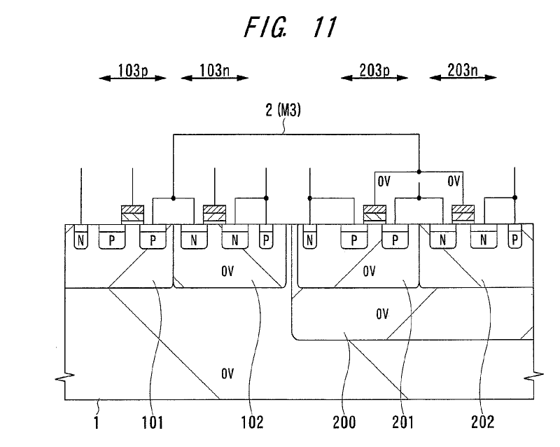

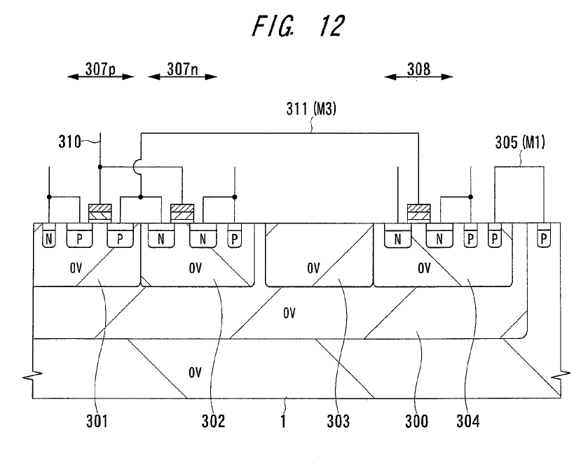

A semiconductor device having a triple well structure according to a first embodiment will be described with reference to FIG. 9 to FIG. 12. Here, one example where the first method is implemented to positive charging will be described. FIG. 9 is a circuit diagram showing one example of an I/O (input and output) circuit unit and a logic circuit unit configuring the audio and image processing apparatus shown in FIG. 1 according to the first embodiment, FIG. 10 is a cross-sectional view of main parts of a region including a pMIS and an nMIS configuring an inverter circuit applied with the first method according to the first embodiment, FIG. 11 is a schematic cross-sectional view of a circuit device for describing the inverter circuit applied with the abovedescribed first method according to the first embodiment, and FIG. 12 is a schematic cross-sectional view of a circuit device for explaining MIS applied with the abovedescribed first method according to the first embodiment.

As shown in FIG. 9, the deep n-type wells 200 and 300 are formed in different regions from each other in the p-type substrate 1 in the logic circuit unit. The deep n-type wells 200 and 300 are not electrically connected to the substrate 1 according to necessity regarding circuit design for power source voltage supply. Note that, other than the deep n-type wells 200 and 300, a plurality of deep n-type wells are formed in the logic circuit unit, but illustrations thereof will be omitted here.

An inverter circuit INV1 which does not fulfill any role in circuit operations is formed in the deep n-type well 200. A shallow n-type well 251 and a shallow p-type well 252 are formed in different regions from each other in the deep n-type well 200, and further, a pMIS 254p is formed in the shallow n-type well 251, and an nMIS 254n is formed in the shallow p-type well 252. The inverter circuit INV1 is comprised of the pMIS 254p and the nMIS 254n. A gate electrode of the pMIS 254p and a gate electrode of the nMIS 254n in the inverter circuit INV1 are connected by using an n-type semiconductor region formed in the shallow n-type well 251 and a wiring 255 in an eighth layer (M8). Wiring connections for configuring the inverter circuit INV1 except for a gate electrode of the pMIS 254p and a gate electrode of the nMIS 254n is performed by using wirings in a first layer. A wiring connection between the gate electrode of the pMIS 254p and the gate electrode of the nMIS 254n is performed simultaneously with formation of the gate electrodes. The shallow p-type well 252 is connected to the substrate 1 by a wiring 253 (M1) of the first layer.

FIG. 10 shows a cross-sectional view of main parts of a region including the pMIS 254p and the nMIS 254n configuring the inverter circuit INV1. The gate electrode of the pMIS 254p formed in the shallow n-type well 251 has a structure obtained by stacking a polysilicon film 503 added with, for example, a p-type impurity and a silicide layer 505, while the gate electrode of the nMIS 254n formed in the shallow p-type well 252 has a structure obtained by stacking a polysilicon film 504 added with, for example, an n-type impurity and a silicide layer 505, and the gate electrode of the pMIS 254p and the gate electrode of the nMIS 254n are connected by the silicide layer 505. The gate electrode 503 of the pMIS 254p and the gate electrode 504 of the nMIS 254n are electrically connected to the shallow n-type well 251 via wirings M1 to M8 in the first layer to the eighth layer. The shallow p-type well 252 is electrically connected to the substrate 1 via the wiring 253 (M1) of the first layer.

The pMIS 203p and the nMIS 203n configuring an inverter circuit which fulfills a predetermined role in circuit operations are formed in the deep n-type well 200. The gate electrode of the pMIS 203p and the gate electrode of the nMIS203n in the inverter circuit are connected to a region outside the deep n-type well 200, for example, the drain of pMIS 103p and the drain of nMIS 103n formed in an I/O circuit unit using the wiring 2 (M3) of the third layer.

The shallow n-type well 204 and the shallow p-type well 205 are formed in different regions from each other in the deep n-type well 200, and the shallow p-type well 205 is electrically connected to the substrate 1 by the wiring 206 (M1) of the first layer from necessity regarding the circuit. Many inverter circuits including an inverter circuit comprised of the pMIS 207p and the nMIS 207n are formed in the shallow n-type well 204 and the shallow p-type well 205, but the gate electrodes in the inverter circuits are connected to predetermined portions of the circuits using either of wirings up to the third layer. Therefore, a function for preventing charging of the deep n-type well 200 cannot be expected in the shallow p-type well 205 in steps after the step of forming the wirings of the third layer.

The inverter circuit INV2 which does not fulfill any role in circuit operations is formed also in the deep n-type well 300. A shallow n-type well 351 and a shallow p-type well 352 are formed in different regions from each other in the deep n-type well 300, a pMIS 354p is formed in the shallow n-type well 351, and an nMIS 354n is formed in the shallow p-type well 352. The inverter circuit INV2 is comprised of the pMIS 354p and the nMIS 354n. A gate electrode of the pMIS 354p and a gate electrode of the nMIS 354n in the inverter circuit INV2 are connected to a p-type semiconductor region formed in the shallow p-type well 352 by using a wiring 355 (M8) of the eighth layer. Wiring connections for configuring the inverter circuit INV2 except for a gate electrode of the pMIS 354p and a gate electrode of the nMIS 354n is performed using wirings of the first layer. Wiring connections between the gate electrode of the pMIS 354p and the gate electrode of the nMIS 354n are performed simultaneously with formation of the gate electrodes. The shallow p-type well 352 is connected to the substrate 1 by a wiring 353 (M1) of the first layer.

Further, the nMIS 308 is formed in the shallow p-type well 304 formed in the deep n-type well 300, the gate electrode of the nMIS 308 is connected to an output stage of the inverter circuit comprised of the pMIS 307p formed in the shallow n-type well 301 and the nMIS 307n formed in the shallow p-type well 302 using the wiring 311 (M3) of the third layer. The shallow p-type well 304 having the nMIS 308 is electrically connected to the substrate 1 by the wiring 305 (M1) of the first layer from necessity regarding the circuit. Many inverter circuits containing an inverter circuit including the nMIS 309n as a constituent component is formed in the shallow p-type well 304, but gate electrodes in the inverter circuits are connected to predetermined portions of the circuits using either of wirings up to the third layer. Therefore, a function of preventing charging of the deep n-type well 300 cannot be expected in the shallow p-type well 304 in the steps after the step for forming the wirings of the third layer.

Next, an effect obtained by the first method according to the first embodiment will be described with reference to FIG. 11. FIG. 11 is a schematic cross-sectional view describing an aspect that the deep n-type well 200 in the semiconductor device is charged at a step of forming connection holes in an interlayer insulating film formed on the wirings of the third layer.

At this stage (the step of forming connection holes in the interlayer insulating film formed on the wirings of the third layer), the gate electrode of the pMIS 254p and the gate electrode of the nMIS 254n configuring the inverter circuit INV1 are in a floating state, so that positive charges flowed in the deep n-type well 200 by plasma discharge are discharged to the substrate 1 via the inverter circuit INV1 and the wiring 253 (M1). Therefore, in the inverter circuit comprised of the pMIS 203p and the nMIS 203n formed in the deep n-type well 200, despite the gate electrode is connected to the drain of the nMIS 103n formed in the substrate 1, a potential difference does not occur in the gate insulating film, and thus breakdown does not occur. Note that, some of the drains may be charged positively due to charging of the shallow n-type well 101. In such a case, a potential difference occurs in the gate insulating films of the pMIS 203p and the nMIS 203n configuring the inverter circuit. However, since the area of the shallow n-type well 101 is small, a charging amount is small so that breakdown is prevented from occurring in the gate insulating film. Similarly, breakdown of a gate insulating film of MIS is suppressed even in other circuit constituent components. While the charging state at the step of forming connection holes in the interlayer insulating film formed on wirings of the third layer has been shown in FIG. 11 described above, charges flowed in the deep n-type well 200 are discharged until to a step of forming connection holes in an interlayer insulating film formed on wirings of the seventh layer, so that breakdown of the gate insulating film of MIS is suppressed. Further, at a step of forming connection holes in an insulating film formed on wirings of the eighth layer, a charging amount of the deep n-type well 200 is small and thus breakdown of the gate insulating layer of MIS does not occur.

Next, other effects obtained by the first method according to the first embodiment will be described with reference to FIG. 12. FIG. 12 is a schematic cross-sectional view describing an aspect that the deep n-type well 300 in the semiconductor device is charged in the step of forming connection holes in an interlayer insulating layer formed on wirings of the third layer.

Also in this stage (the step of forming connection holes in the interlayer insulating film formed on the wirings of the third layer), since the gate electrode of the pMIS 354p and the gate electrode of the nMIS 354n configuring the inverter circuit INV2 are in a floating state, positive charges flowed in the deep n-type well 300 by plasma discharge are discharged to the substrate 1 via the inverter circuit INV2 and the wiring 353 (M1). Thereby, discharging of all shallow n-type wells and shallow p-type wells in the deep n-type well 300 are prevented. In this manner, in the nMIS 308 formed in the deep n-type well 300, despite the gate electrode is in connection with the drain of the nMIS 307n formed in the other shallow p-type well 302, a potential difference does not occur in the gate insulating film, and thus breakdown does not occur.

### Second Embodiment

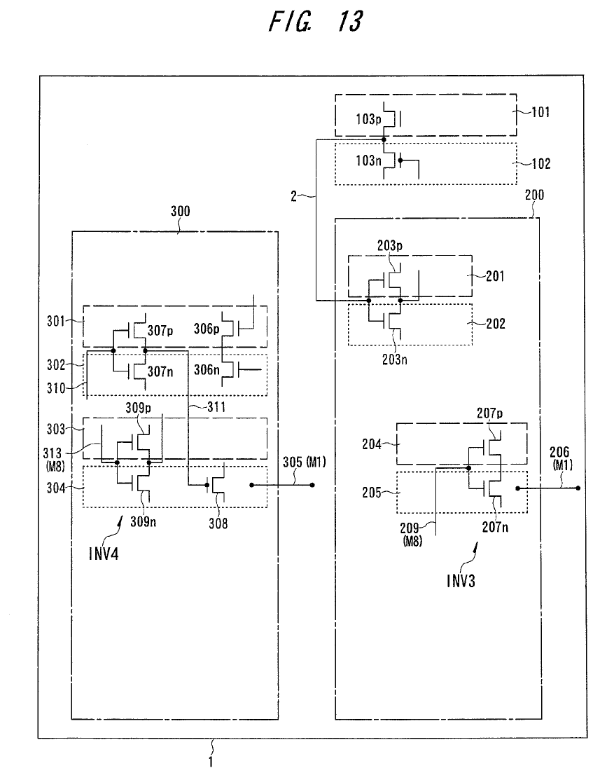

A semiconductor device having a triple well structure according to a second embodiment will be described with reference to FIG. 13. Here, another example where a first method different from the abovedescribed first embodiment is implemented with respect to positive charging will be described. FIG. 13 is a circuit diagram showing one example of an I/O (input and output) circuit unit and a logic circuit unit according to the second embodiment configuring the audio and image processing apparatus shown in FIG. 1 described above.

As shown in FIG. 13, the inverter circuit INV1 comprising the pMIS 254p and the nMIS 254n which do not contribute to circuit operations and is formed in the semiconductor device of the abovedescribed first embodiment, the shallow n-type well 251 including the pMIS 254p, and the shallow p-type well 252 including the nMIS 254n are not formed in the deep n-type well 200. Instead of this configuration, a function of preventing charging of the deep n-type well 200 is provided to an inverter circuit INV3 comprised of a pMIS 207p and an nMIS 207n by performing the connection between the shallow p-type well 205 and the substrate 1 using the first layer wiring 206 (M1) and performing a connection between a gate electrode of the inverter circuit INV3 and a predetermined portion of the circuit using wirings 209 (M8) of the eighth layer which is the upper most layer.

On the other hand, the inverter circuit INV2 comprised of the pMIS 354p and the nMIS 354n which does not contribute to circuit operation and is formed in the semiconductor device according to the abovedescribed first embodiment, the shallow n-type well 351 including the pMIS 354p, and the shallow p-type well 352 including the nMIS 354n are not formed in the deep n-type well 300. Instead of this configuration, the connection between the shallow p-type well 304 and the substrate is performed using the wiring 305 (M1) of the first layer, and connections of gate electrodes of an inverter circuit INV4 comprised of a pMIS 309p and an nMIS 309n and a predetermined portion of the circuit is performed using a wiring 313 (M8) of the eighth layer which is the uppermost layer. Configurations and so forth of other circuits are similar to those in the first embodiment.

Next, an effect obtained according to the second embodiment will be described.

In the second embodiment, the gate electrode of the inverter circuit INV3 comprised of the pMIS 207p and the nMIS 207n, and the gate electrode of the inverter circuit INV4 comprised of the pMIS 309p and the nMIS 309n are maintained in a floating state until just before a step of forming wirings of the eighth layer which is the uppermost layer, and the shallow p-type well 205 including the nMIS 207n and configuring the inverter circuit INV3 and the shallow p-type well 304 including the nMIS 309n and configuring the inverter circuit INV4 are connected to the substrate 1 by using the wirings 206 (M1) and 305 (M1) of the first layer, respectively. Thereby, positive charges flowed in the deep n-type wells 200 and 300 are discharged to the substrate 1 until a step of forming connection holes in an interlayer insulating film formed on the wirings of the seventh layer like the first embodiment described above. As a result, breakdown of the gate insulating film occurring in the pMIS 203p or the nMIS 203n configuring the inverter circuit and breakdown of the gate insulating film occurring in the nMIS 308 can be suppressed.

### Third Embodiment

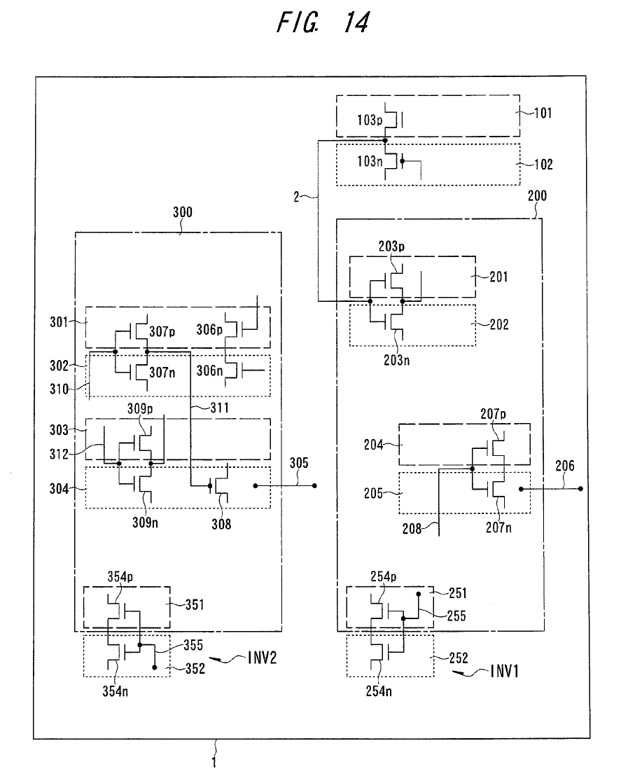

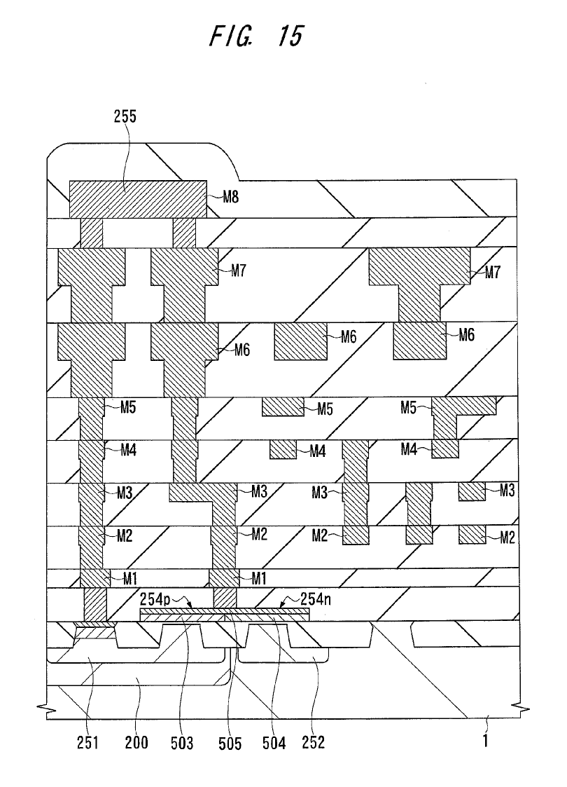

A semiconductor device having a triple well structure according to a third embodiment will be described with reference to FIG. 14 and FIG. 15. Here, another example where the first method is implemented to positive charging, different from the first and second embodiments described above. FIG. 14 is a circuit diagram showing one example of an I/O (input and output) circuit unit and a logic circuit unit according to the third embodiment configuring the audio and image processing apparatus shown in FIG. 1 described above and FIG. 15 is a cross-sectional view of main parts of a region including a pMIS and an nMIS configuring an inverter circuit to which the abovedescribed first method is applied according to the third embodiment.

As shown in FIG. 14, in the pMIS 254p and nMIS 254n configuring the inverter circuit INV1 for preventing charging of the deep n-type well 200, the nMIS 254n is different from that of the first embodiment, and it is formed in the shallow p-type well 252 formed in the substrate 1. The nMIS 354n of the pMIS 354p and the nMIS 354n configuring the inverter circuit INV2 for preventing charging of the deep n-type well 300 is different from that of the abovedescribed first embodiment and it is formed in the shallow p-type well 352 formed in the substrate 1. The shallow p-type wells 252 and 352 are formed in the substrate 1 and they are electrically connected to the substrate 1 spontaneously so that connection with the substrate 1 using wirings is not required. Configurations and so forth of the other circuits are similar to that of the abovedescribed first embodiment.

FIG. 15 shows a cross-sectional view of main parts of a region including the pMIS 245p and the nMIS 254n configuring the inverter circuit INV1. The gate electrode of the pMIS 254p formed on the shallow n-type well 251 has, for example, a structure obtained by stacking a polysilicon film 503 to which a p-type impurity is added and a silicide layer 505, while the gate electrode of the nMIS 254n formed in the shallow p-type well 252 has, for example, a structure obtained by stacking a polysilicon film 504 to which an n-type impurity is added and a silicide layer 505, where the gate electrode of the pMIS 254p and the gate electrode of the nMIS 254n are connected by the silicide layer 505. The gate electrode of the pMIS 254p and the gate electrode of the nMIS 254n are electrically connected to the shallow n-type well 251 via wirings M1 to M8 of the first layer to the eighth layer. The shallow p-type well 252 is formed in the p-type substrate 1 and it is electrically connected to the substrate 1.

### Fourth Embodiment

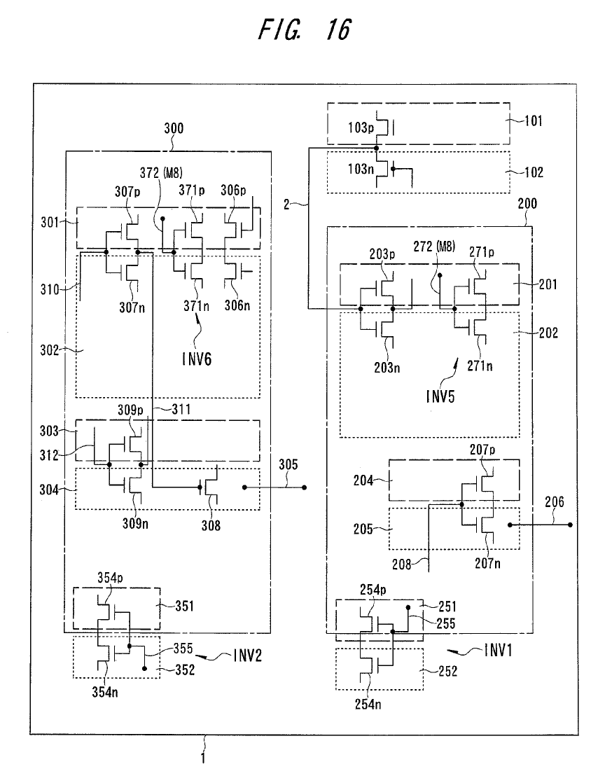

A semiconductor device having a triple well structure according to a fourth embodiment will be described with reference to FIG. 16. Here, one example where the first method is implemented to negative charging will be described. FIG. 16 is a circuit diagram showing one example of an I/O (input and output) circuit unit and a logic circuit unit according to the fourth embodiment configuring the audio and image processing apparatus shown in FIG. 1 described above.

As shown in FIG. 16, since areas of the shallow p-type well 202 formed in the deep n-type well 200 and the shallow p-type well 302 formed in the deep n-type well 300 are large, when the shallow p-type wells 202 and 302 are put in a situation that they are charged negatively, the charging amounts become large so that breakdown of MIS occurs easily. Therefore, in order to prevent the shallow p-type wells 202 and 302 from being charged negatively, an inverter circuit INV5 1comprised of a pMIS 271p and an nMIS 271n is formed in the deep n-type well 200, and an inverter circuit INV6 comprised of a pMIS 371p and an nMIS 371n is formed in the deep n-type well 300. In the inverter circuit INV5, a gate electrode of the pMIS 271p and a gate electrode of the nMIS 271n are connected simultaneously with processing, and the gate electrodes and the shallow n-type well 201 are connected by a wiring 272 (M8) of the eighth layer which is the uppermost layer.

In the same manner, in the inverter circuit IVN6, a gate electrode of the pMIS 371p and a gate electrode of the nMIS 371n are connected simultaneously with processing, and the gate electrodes and the shallow n-type well 301 are connected by a wiring 372 (M8) of the eighth layer which is the uppermost layer. The other wiring connections for configuring the inverter circuit are performed using wirings of the first layer. The other circuit configuration or the like is similar to that of the third embodiment described above.

Next, an effect obtained by the fourth embodiment will be described.

In the fourth embodiment, since the gate electrode of the inverter circuit INV5 comprised of the pMIS 271p and the nMIS 271n is maintained in a floating state until just before a step of forming wirings of the eighth layer which is the uppermost layer, the shallow p-type well 202 and the deep n-type well 200 are maintained in a conducted state to each other via the shallow n-type well 201 until a step of forming connection holes in an interlayer insulating film formed on wirings of the seventh layer. As a result, negative charges flowed in the shallow p-type well 202 are discharged to the substrate 1 via the shallow n-type well 201 and the deep n-type well 200. Similarly, since the gate electrode of the inverter circuit INV6 comprised of the pMIS 371p and the nMIS 371n is maintained in a floating state until just before a forming step of wirings of the eighth layer which is the uppermost layer, the shallow p-type well 302 and the deep n-type well 300 are maintained in a conducted state to each other via the shallow n-type well 301 until the step of forming connection holes in an interlayer insulating film formed on wirings of the seventh layer. As a result, negative charges flowed in the shallow p-type well 302 are discharged to the substrate 1 via the shallow n-type well 301 and the deep n-type well 300. Positive charging of the deep n-type wells 200 and 300 is also prevented by adopting a configuration similar to that of the third embodiment described above. Thereby, breakdown of the gate insulating film generated in the pMIS 203p and the nMIS 203n configuring the inverter circuit and breakdown of the gate insulating film generated in the nMIS 308 can be suppressed.

### Fifth Embodiment

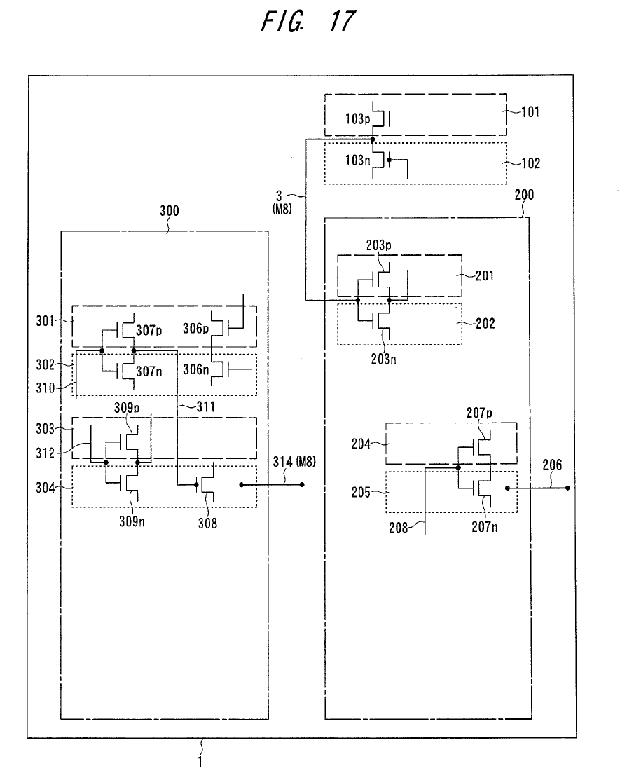

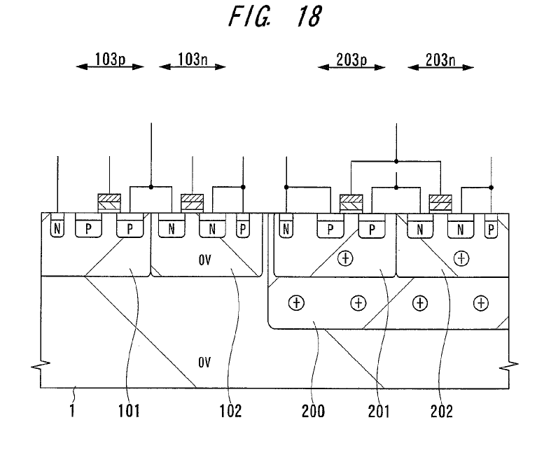

A semiconductor device having a triple well structure according to a fifth embodiment will be described with reference to FIG. 17 to FIG. 19. Here, one example where the second method is implemented with respect to positive charging will be described. FIG. 17 is a circuit diagram showing one example of an I/O (input and output) circuit unit and a logic circuit unit configuring the audio and image processing apparatus shown in FIG. 1 described above according to the fifth embodiment, FIG. 18 is a schematic cross-sectional view of circuit elements for describing an inverter circuit applied with the abovedescribed second method according to the fifth embodiment, and FIG. 19 is a schematic cross-sectional view of circuit elements for describing MISes applied with the abovedescribed second method according to the fifth embodiment.

As shown in FIG. 17, in the deep n-type well 200, the inverter circuit INV1 comprised of the pMIS 254p and the nMIS 254n which does not contribute to circuit operations, the shallow n-type well 251 including the pMIS 254p, and the shallow p-type well 252 including the nMIS 254n are not formed like the abovedescribed second embodiment. Instead of forming the inverter circuit for charging prevention, a connection between the gate electrodes of the pMIS 203p and the nMIS 203n configuring the inverter circuit and a drain (an n-type semiconductor region formed in the shallow p-type well 102) of the nMIS 103n is performed by using a wiring 3 (M8) of the eighth layer which is the uppermost layer in order to prevent application of a voltage to the gate insulating films of the pMIS 203p and the nMIS 203n configuring the inverter circuit even if the deep n-type well 200 is charged.

Even in the deep n-type well 300, the inverter circuit INV2 comprising the pMIS 354p and the nMIS 354n which does not contribute to circuit operation, the shallow n-type well 351 including the pMIS 354p and the shallow p-type well 352 including the nMIS 354n are not formed. Connection between the shallow p-type well 304 and the substrate 1 is performed using a wiring 314 (M8) of the eighth layer which is the uppermost layer. The other circuit configuration or the like is similar to that of the abovedescribed first embodiment.

Next, an effect obtained by the second method according to the fifth embodiment will be described with reference to FIG. 18. FIG. 18 is a schematic cross-sectional view for describing an aspect where a semiconductor device is charged by plasma discharge at a step of forming connection holes in an interlayer insulating film formed on wirings of the seventh layer.

At this stage (the step of forming connection holes in an interlayer insulating film formed on wirings of the seventh layer) in a series of manufacturing steps, the gate electrode of the pMIS 203p and the gate electrode of the nMIS 203n configuring the inverter circuit are not connected to the drain of the nMIS 103n in the substrate 1, and potential difference does not occur in the gate insulating film, and thus breakdown does not occur. Since other circuit constituent components provided in the deep n-type well 200 and required to be connected to the substrate 1 are connected to the substrate 1 by wirings of the eighth layer, breakdown of the gate insulating film of the MIS is suppressed in the same manner. Note that, since the deep n-type well 200 and the substrate 1 are not connected at a step before the step of forming connection holes in an interlayer insulating film formed on wirings of the seventh layer, breakdown of the gate insulating film of MIS is suppressed. Since a charging amount of the deep n-type 200 is small at the step of forming connection holes in the insulating film formed on wirings of the eighth layer, breakdown does not occur in the gate insulating film of the MIS.

Next, another effect obtained by the second method according to the fifth embodiment will be described with reference to FIG. 19. FIG. 19 is a schematic cross-sectional view for describing an aspect where the deep n-type well 300 is charged at the step of forming connection holes in an interlayer insulating film formed on wirings of the seventh layer.

Since the shallow p-type well 304 is not connected to the substrate 1 at this stage (step of forming connection holes in an interlayer insulating film formed on wirings of the seventh layer), as a result of the entire deep n-type well 300 being charged, a potential difference does not occur in the gate insulating film of the nMIS 308, and thus breakdown does not occur. Similarly, breakdown of the gate insulating film of MIS is suppressed in the other circuit constituent components. Note that, since the shallow p-type well 304 is isolated from the substrate 1 even at steps before the step of forming connection holes in an interlayer insulating film formed on wirings of the seventh layer, breakdown does not occur in the gate insulating film of MIS. Further, similar to the deep n-type well 200, since the charged amount of the deep n-type well 300 is small at a step of forming connection holes in an insulating film formed on wirings of the eighth layer, breakdown does not occur in the gate insulating film of MIS.

Note that, in the fifth embodiment, the case where the second method is applied to the connection between the gate electrode of the inverter circuit comprised of the pMIS 203p and the nMIS 203n and the drain of the nMIS 103n, and the case where the second method is applied to the connection between the shallow p-type well 304 formed with the nMIS 308 and the substrate 1 have been exemplified; however, the present invention is not limited to these cases.

### Sixth Embodiment

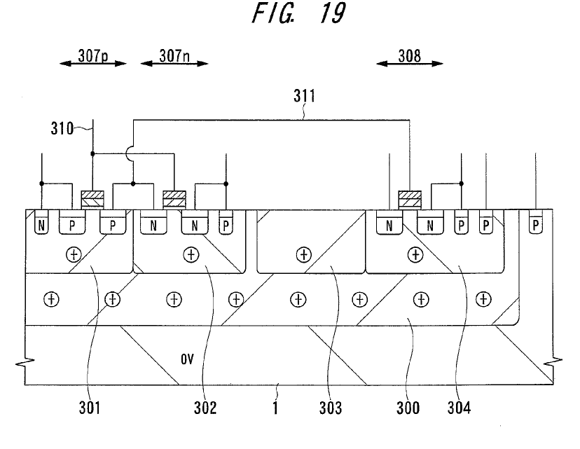

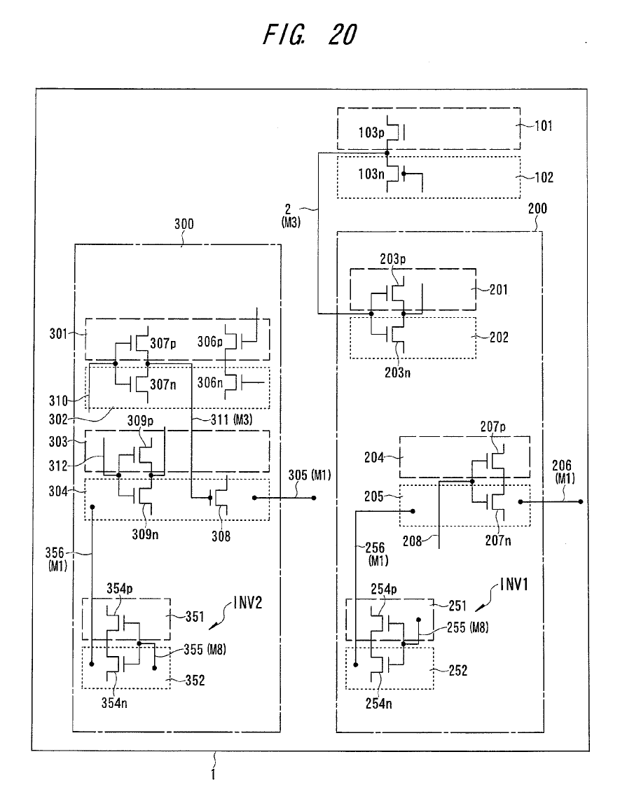

A semiconductor device having a triple well structure according to a sixth embodiment will be described with reference to FIG. 20. Here, another example where the first method different from the first, second and third embodiments described above is implemented to positive charging. FIG. 20 is a circuit diagram showing one example of an I/O (input and output) circuit unit and a logic circuit unit according to the sixth embodiment configuring the audio and image processing apparatus shown in FIG. 1 described above.

As shown in FIG. 20, the shallow p-type well 252 having formed thereto the nMIS 254n of the pMIS 254p and the nMIS 254n configuring the inverter circuit INV1 for preventing charging of the deep n-type well 200 is different from that in the abovedescribed first embodiment, and it is electrically connected to the shallow p-type well 205 by a wiring 256 (M1) of the first layer. Since the shallow p-type well 205 is connected to the substrate 1 by the wiring 206 (M1) of the first layer, the shallow p-type well 252 is indirectly connected to the substrate 1 via the shallow p-type well 205.

The shallow p-type well 352 having formed thereto the nMIS 354n of the pMIS 354p and the nMIS 354n configuring the inverter circuit INV2 for preventing charging of the deep n-type well 300 is different from that in the abovedescribed first embodiment, and it is electrically connected to the shallow p-type well 304 by a wiring 356 (M1) of the first layer. Since the shallow p-type well 304 is connected to the substrate 1 by the wiring 305 (M1) of the first layer, the shallow p-type well 352 is indirectly connected to the substrate 1 via the shallow p-type well 304. Configurations and so forth of the other circuits are similar to those of the abovedescribed first embodiment.

### Seventh Embodiment

A semiconductor device having a triple well structure according to a seventh embodiment will be described. In the abovedescribed first, third, or sixth embodiment, positive charges flowed in the deep n-type well 200, the shallow n-type well 201, or the shallow p-type well 202 by plasma discharge are discharged to the substrate 1, for example, by using the inverter circuit INV1, and positive charges flowed in the deep n-type well 300 by plasma discharge are discharged to the substrate 1, for example, by using the inverter circuit INV2. Meanwhile, in this seventh embodiment, a discharge countermeasure circuit which can obtain an effect similar to that obtained in the abovedescribed first, third, or sixth embodiment without using the inverter circuit will be described. A first example to a thirteenth example of the discharge countermeasure circuit will be described below, and it is needless to say that these examples are typical examples and various modifications can be made without departing from the scope of the present invention.

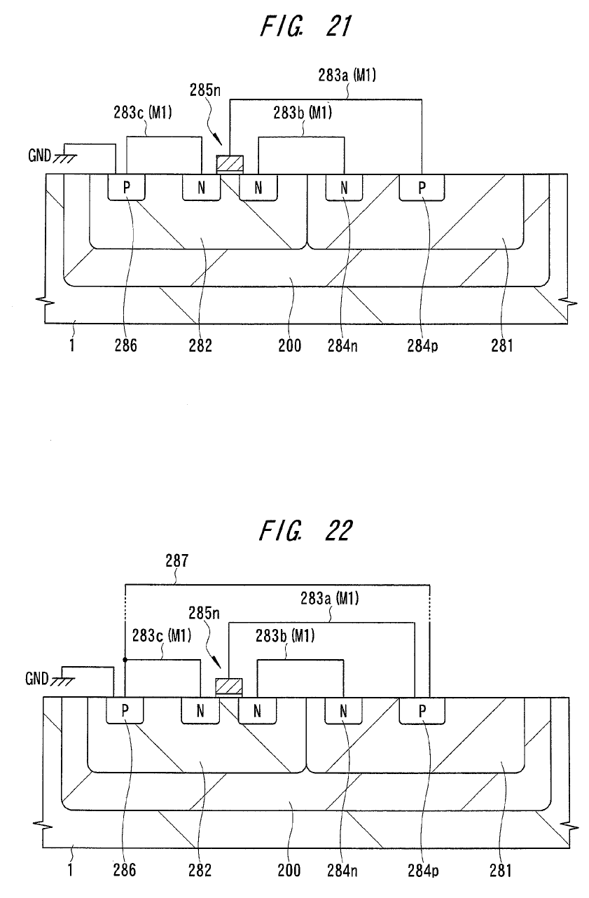

A discharge countermeasure circuit of the first example according to the seventh embodiment will be described. A schematic cross-sectional view of the discharge countermeasure circuit of the first example is shown in FIG. 21. A shallow n-type well 281 and a shallow p-type well 282 are formed in different regions in the deep n-type well 200, an n-type semiconductor region 284n and a p-type semiconductor region 284p are formed in different regions from in the shallow n-type well 281, and an nMIS 285n is formed in the shallow p-type well 282. Further, the gate electrode of the nMIS 285n and the p-type semiconductor region 284p formed in the shallow n-type well 281 are connected by a wiring 283a, the drain of the nMIS 285n and the n-type semiconductor region 284n formed in the shallow n-type well 281 are connected by a wiring 283b, and the source of the nMIS 285n is connected to a ground potential GND by a wiring 283c via a p-type semiconductor region 286 formed in the shallow p-type well 282. Wirings of the first layer are used as these wirings 283a, 283b, and 283c. The discharge countermeasure circuit of the first example is comprised of the n-type semiconductor region 284n and the p-type semiconductor region 284p formed in the shallow n-type well 281, the nMIS 285n formed in the shallow p-type well 282, and the like, and it does not fulfill any role in circuit operation of the semiconductor device.

For example, when many positive charges are accumulated in the deep n-type well 200 and the shallow n-type well 281 due to plasma discharge during manufacturing steps, the potential of the p-type semiconductor region 284p and the potential of the shallow n-type well 281 becomes approximately equal to each other due to a pn junction capacitance. Thereby, when a potential larger than a threshold voltage is applied to the gate electrode of the nMIS 285n, the nMIS 285n is turned ON, so that positive charges flowed in the deep n-type well 200 and the shallow n-type well 281 are discharged to the ground potential GND via the wiring 283b, the channel of the nMIS 285n, the wiring 283c, and the p-type semiconductor region 286.

A discharge countermeasure circuit of the second example according to the seventh embodiment will be described. A schematic cross-sectional view of the discharge countermeasure circuit of the second example is shown in FIG. 22. The discharge countermeasure circuit of the second example has a circuit configuration similar to that of the abovedescribed discharge countermeasure circuit of the first example but a difference of the discharge countermeasure circuit of the second example from the discharge countermeasure circuit of the first example lies in that the p-type semiconductor region 284p formed in the shallow n-type well 281 and the p-type semiconductor region 286 formed in the shallow p-type well 282 are connected by a wiring 287 formed at a step performed after a step where breakdown of the gate insulating film may occur due to plasma discharge. It is desirable that the wiring connection is performed by using a wiring of the uppermost layer. In this manner, by fixing the p-type semiconductor region 284p to the ground potential GND and always putting the nMIS 285n in an OFF state during circuit operations of the semiconductor device, the nMIS 285n is prevented from exerting such an adverse effect as leakage to another circuit.

A discharge countermeasure circuit of the third example according to the seventh embodiment will be described. The discharge countermeasure circuit of the third example has, for example, a configuration similar to that of the discharge countermeasure circuit of the first example or the second example, and the thickness of the gate insulating film of the nMIS 285n is set to 10 nm or more. For example, the thickness may be equal to that of the gate insulating film of a MISFET formed in the I/O (input and output) circuit unit. By forming the gate insulating film of the nMIS 285n thickly, leakage is reduced, thereby achieving a reliable operation.

A discharge countermeasure circuit of the fourth example according to the seventh embodiment will be described. A schematic plan view and a schematic sectional view of the discharge countermeasure circuit of the fourth example are shown in FIGS. 23A and 23B respectively. The discharge countermeasure circuit of the fourth example has a configuration similar to that of the abovedescribed discharge countermeasure circuit of the first example, but a difference of the discharge countermeasure circuit of the fourth example from the abovedescribed discharge countermeasure circuit of the first example lies in that wirings are comprised of a shared contact and a conductor film (for example, a stacked film formed of a polysilicon film and a silicide film) of the same layer as the gate electrode are used as connection wirings instead of using the wirings 283a, 283b, and 283c.

That is, the gate electrode of the nMIS 285n and the p-type semiconductor region 284p formed in the shallow n-type well 281 are connected by a plug electrode PLG buried in a connection hole CNT formed so as to span the both. A drain of the nMIS 285n and the n-type semiconductor region 284n formed in the shallow n-type well 281 are connected by a plug electrode PLG by forming a wiring 288a formed of a conductor film of the same layer as the gate electrode between the both and utilizing a plug electrode PLG buried in the connection hole CNT formed so as to span the wiring 288a and the drain of the nMIS 285n and a plug electrode PLG embedded in a connection hole CNT formed so as to span the wiring 288a and the n-type semiconductor region 284n. A source of the nMIS 285n and the p-type semiconductor region 286 formed in the shallow p-type well 282 are connected by forming a wiring 288b formed of a conductor film of the same layer as the gate electrode between the both, and utilizing a plug electrode PLG buried in a connection hole CNT formed so as to span the wiring 288b and the source of the nMIS 285n and a plug electrode PLG embedded in a connection hole CNT formed so as to span the wiring 288b and the p-type semiconductor region 286.

In this manner, for example, even if charging due to plasma discharge is feared to occur in wirings of the first layer, since the wirings 283a, 283b, and 283c comprised of wirings of the first layer are not used for the charge countermeasure circuit, charging can be prevented.

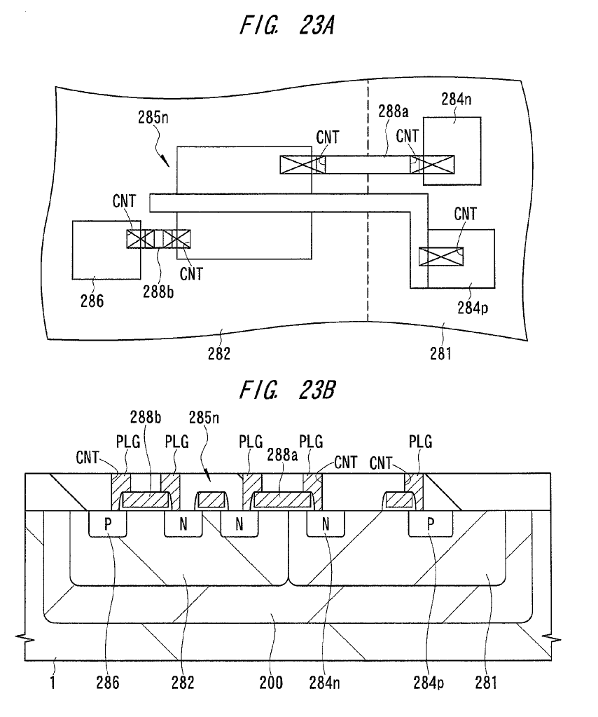

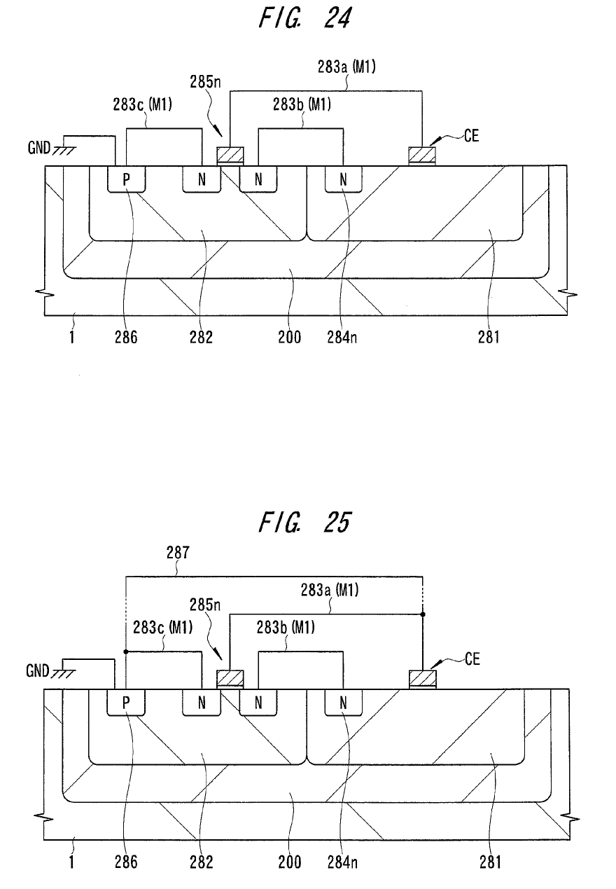

A discharge countermeasure circuit of the fifth example according to the seventh embodiment will be described. A schematic cross-sectional view of the discharge countermeasure circuit of the fifth example is shown in FIG. 24. While the discharge countermeasure circuit of the fifth example has a configuration similar to that of the abovedescribed discharge countermeasure circuit of the first example, a difference of the discharge countermeasure circuit of the fifth example from the abovedescribed discharge countermeasure circuit of the first example lies in that a capacitor element CE formed on the shallow n-type well 281 is used instead of the p-type semiconductor region 284p. Like the abovedescribed discharge countermeasure circuit of the first example, for example, when many positive charges are accumulated in the deep n-type well 200 and the shallow n-type well 281 due to plasma discharge during manufacturing steps, the potential of the gate of the capacitor element CE and the potential of the shallow n-type well 281 become approximately equal to each other by the gate capacitance of the capacitor element CE. Thereby, when a potential larger than the threshold voltage is applied to the gate electrode of the nMIS 285n, the nMIS 285n is turned ON, so that positive charges flowed in the deep n-type well 200 and the shallow n-type well 281 are discharged into the ground potential GND via the wiring 283b, the channel of the nMIS 285n, the wiring 283c, and the p-type semiconductor region 286. The capacitor element CE can be configured by the shallow n-type well 281, an insulating film of the same layer as the gate insulating film of the nMIS 285n, and a conductor film of the same layer as the gate electrode of the nMIS 285n.

A discharge countermeasure circuit of the sixth example according to the seventh embodiment will be described. A schematic cross-sectional view of the discharge countermeasure circuit of the sixth example is shown in FIG. 25. While the discharge countermeasure circuit of the sixth example has a configuration similar to that of the abovedescribed discharge countermeasure circuit of the fifth example, a difference of the discharge countermeasure circuit of the sixth example from the abovedescribed discharge countermeasure circuit of the fifth example lies in that the gate of the capacitor element CE formed on the shallow n-type well 281 and the p-type semiconductor region 286 formed in the shallow p-type well 282 are connected by a wiring 287 formed at a step performed after the step where breakdown may occur in the gate insulating film due to plasma discharge. It is desirable that the wiring connection is performed by using wirings of the uppermost layer. By fixing the gate of the capacitor element CE to the ground potential GND and always putting the nMIS 285n in OFF state during circuit operations in this manner, the nMIS 285n is prevented from exerting adverse effects such as leakage to another circuit.

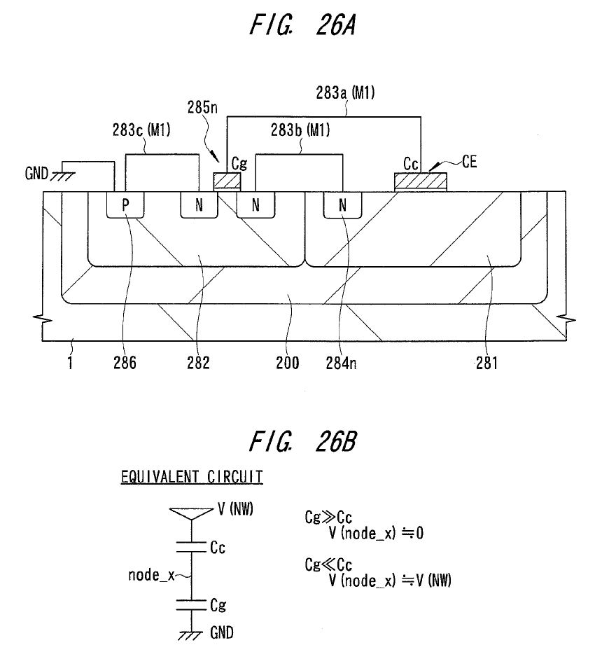

The discharge countermeasure circuit of the seventh example according to the seventh embodiment will be described. A schematic cross-sectional view and an equivalent circuit diagram of the discharge countermeasure circuit of the seventh example are shown in FIGS. 26A and 26B. While the discharge countermeasure circuit of the seventh example has a configuration similar to that of the abovedescribed discharge countermeasure circuit of the fifth example, a difference of the discharge countermeasure circuit of the seventh example from the abovedescribed discharge countermeasure circuit of the fifth example lies in that a gate capacitance Cc of the capacitor element CE is set to be sufficiently larger than a gate capacitance Cg of the nMIS 285n and an input potential (potential applied to the gate electrode) of the nMIS 285n can follow the potential (V(NW)) of the shallow n-type well 281 by coupling.

When the gate capacitance Cc of the capacitor element CE is smaller than the gate capacitance Cg of the nMIS 285n (Cc<<Cg), a voltage (V(node_x)) of the wiring 283a connecting the gate of the capacitor element CE and the gate electrode of the nMIS 285n becomes close to the ground potential GND. On the other hand, when the capacitance Cc of the capacitor element CE is larger than the gate capacitance Cg of the nMIS 285n (Cc>>Cg), the potential of the gate of the capacitor element CE and the potential (V(NW)) of the n-type well 281 become approximately equal to each other, so that the potential (V(NW)) of the shallow n-type well 281 is applied to the gate electrode of the nMIS 285n via the wiring 283a. Thereby, the nMIS 285n is turned ON easily, so that positive charges flowed in the deep n-type well 200 and the shallow n-type well 281 are discharged to the ground potential GND via the wiring 283b, the channel of the nMIS 285n, the wiring 283c, and the p-type semiconductor region 286.

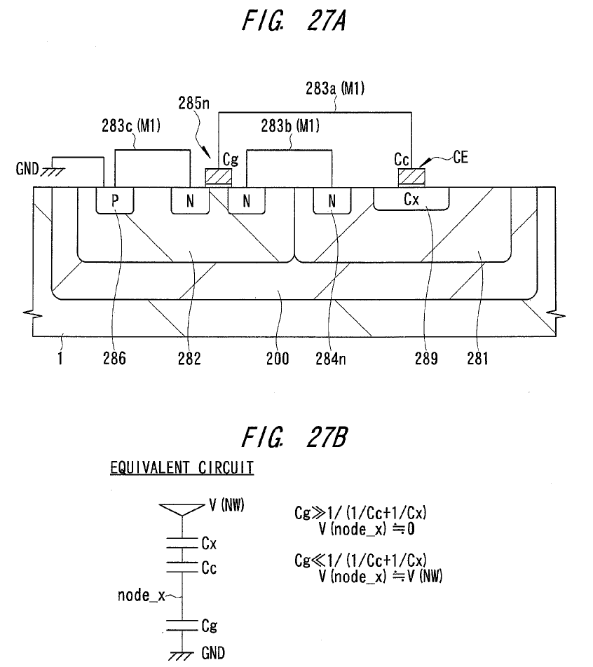

A discharge countermeasure circuit of the eighth example according to the seventh embodiment will be described. A cross-sectional view and an equivalent circuit diagram of the discharge countermeasure circuit of the eighth example are shown in FIGS. 27A and 27B. While the discharge countermeasure circuit of the eighth example has a configuration similar to that of the abovedescribed discharge countermeasure circuit of the fifth example, a difference of the discharge countermeasure circuit of the eighth example from the abovedescribed discharge countermeasure circuit of the fifth example lies in that, in order to compensate for the gate capacitance Cc of the capacitor element CE that is reduced due to a depletion layer 289 formed in the shallow n-type well 281 facing the capacitor element CE, the capacitor element CE is designed with considering the reduction amount.

That is, when the depletion layer 289 is formed in the shallow n-type well 281 facing the capacitor element CE, a capacitance Cx of the depletion layer 289 is connected to the gate capacitance Cc of the capacitor element CE in series, so that an actual gate capacitance of the capacitor element CE becomes smaller than the gate capacitance Cc obtained from design sizes of the capacitor element CE. Therefore, the design of the capacitor element CE obtained by considering a reduction amount of the gate capacitance Cc of the capacitor element CE occurring due to formation of the depletion layer 289 is performed in advance.

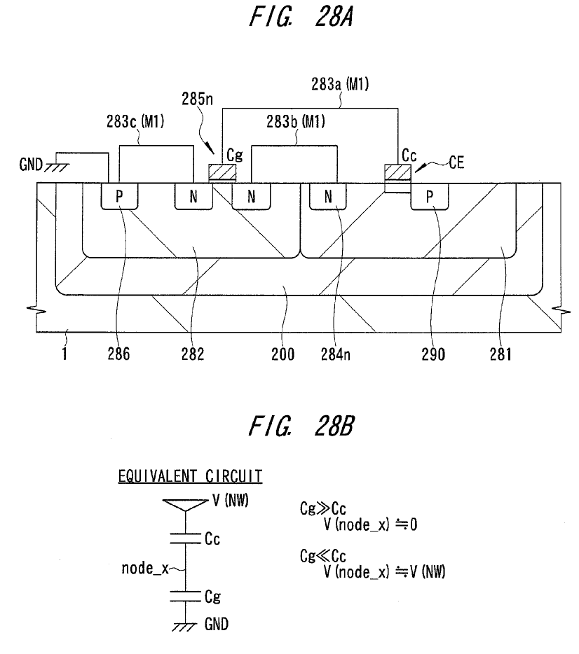

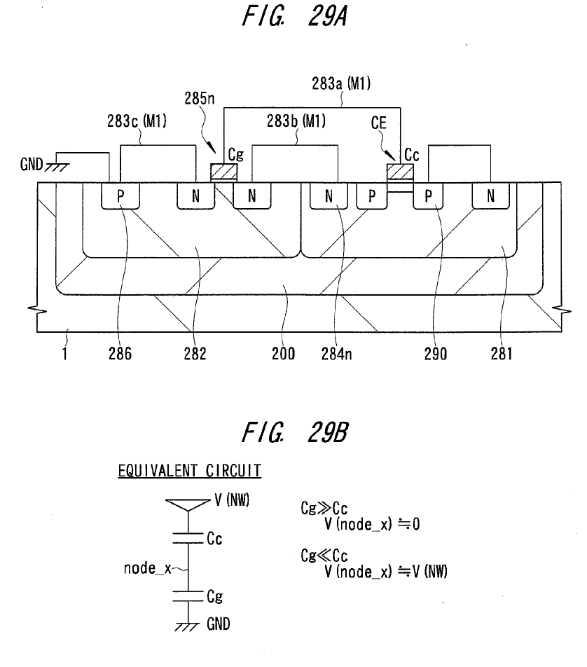

A discharge countermeasure circuit of the ninth example according to the seventh embodiment will be described. A schematic cross-sectional view and an equivalent circuit diagram of the discharge countermeasure circuit of the ninth example are shown in FIGS. 28A and 28B. A schematic cross-sectional view and an equivalent circuit diagram of a modified embodiment of the discharge countermeasure circuit of the ninth example are shown in FIGS. 29A and 29B. While the discharge countermeasure circuit of the ninth example has a configuration similar to that of the abovedescribed discharge countermeasure circuit of the fifth example, a difference of the discharge countermeasure circuit of the ninth example from the abovedescribed discharge countermeasure circuit of the fifth example lies in that, in order to prevent the gate capacitance Cc of the capacitor element CE from decreasing due to a depletion layer formed in the shallow n-type well 281 facing the capacitor element CE, a channel (an inversion layer) is formed at a position of the shallow n-type well 281 facing the capacitor element CE. FIGS. 28A and 28B show a charge countermeasure circuit where a p-type semiconductor region 290 is formed in the n-type well 281 below one side surface of the gate of the capacitor element CE. FIGS. 29A and 29B show a charge countermeasure circuit where p-type semiconductor regions 290 are formed in an n-type well 281 below on both side surfaces of the gate of the capacitor element CE.

That is, when a depletion layer is formed in shallow n-type well 281 facing the capacitor element CE, a capacitance of the depletion layer is connected to the gate capacitance Cc of the capacitor element CE in series, so that it is difficult to obtain the capacitor element CE having a sufficient large capacitance Cc with respect to the gate capacitance Cg of the nMIS 285n. Therefore, in order to prevent formation of the depletion layer, a channel (an inversion layer) is formed at a position of the shallow n-type well 281 facing the capacitor element CE in advance so that reduction of the gate capacitance Cc of the capacitor element CE due to formation of a depletion layer is prevented.

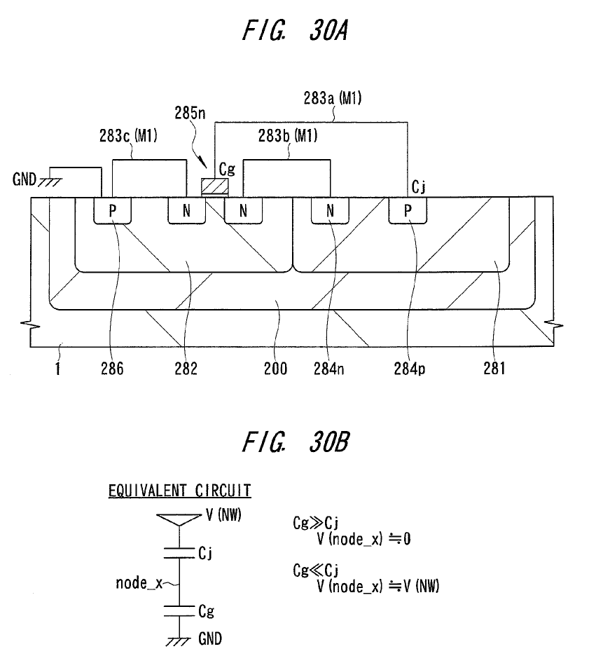

A discharge countermeasure circuit of the tenth example according to the seventh embodiment will be described. A schematic cross-sectional view and an equivalent circuit diagram of the discharge countermeasure circuit of the tenth example are shown in FIGS. 30A and 30B. While the discharge countermeasure circuit of the tenth example has a configuration similar to that of the abovedescribed discharge countermeasure circuit of the first example, a difference of the discharge countermeasure circuit of the tenth example from the abovedescribed discharge countermeasure circuit of the first example lies in that a junction capacitance Cj of the p-type semiconductor region 284p is set to be sufficiently larger than the gate capacitance Cg of the nMIS 285n, and an input potential (potential applied to the gate electrode) of the nMIS 285n can follow the potential (V(NW)) of the shallow n-type well 281 by coupling.

When the junction capacitance Cj of the p-type semiconductor region 284p is larger than the gate capacitance Cg of the nMIS 285n (Cj>>Cg), the potential of the gate of the capacitor element CE and the potential (V(NW)) of the n-type well 281 become approximately equal to each other, so that the potential (V(NW)) of the shallow n-type well 281 is applied to the gate electrode of the nMIS 285n via the wiring 283a. Thereby, the nMIS 285n is turned ON easily, so that positive charges flowed in the deep n-type well 200 and the shallow n-type well 281 are discharged to the ground potential GND via the wiring 283b, the channel of the nMIS 285n, the wiring 283c, and the p-type semiconductor region 286.

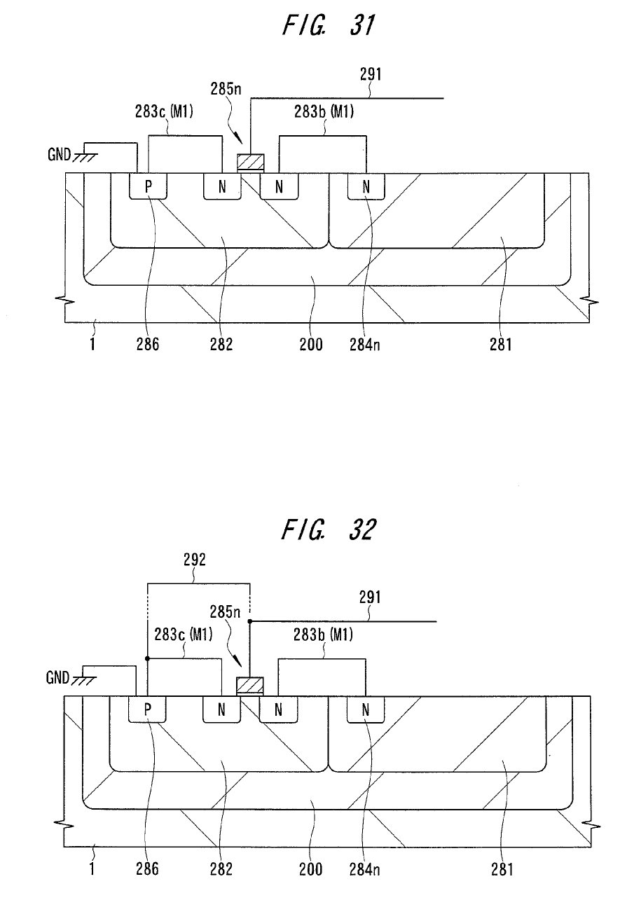

A discharge countermeasure circuit of the eleventh example according to the seventh embodiment will be described. A schematic cross-sectional view of the discharge countermeasure circuit of the eleventh example is shown in FIG. 31. In the discharge countermeasure circuit of the eleventh example, the shallow n-type well 281 and the shallow p-type well 282 are formed in different regions from each other in the deep n-type well 200, and the nMIS 285n is formed in the shallow n-type well 282, but only the n-type semiconductor region 284n is formed in the shallow n-type well 281. The drain of the nMIS 285n and the n-type semiconductor region 284n formed in the shallow n-type well 281 are connected by the wiring 283b and the source of the nMIS 285n is connected to the ground potential GND via the p-type semiconductor region 286 formed in the shallow p-type well 282 by the wiring 283c, and a wiring 291 in a floating state is connected to the gate electrode of the nMIS 285n.

When the nMIS 285n is turned ON due to an intermediate potential of the wiring 291 put in a floating state, positive charges flowed in the deep n-type well 200 and the shallow n-type well 281 are discharged to the ground potential GND via the wiring 283b, the channel of the nMIS 285n, the wiring 283c, and the p-type semiconductor region 286. The wiring 291 is applied with a potential at which the nMIS 285n is turned OFF in a step after a step where breakdown of the gate insulating film may occur due to plasma discharge, so that the nMIS 285n is prevented from exerting adverse effect such as leakage to another circuit.

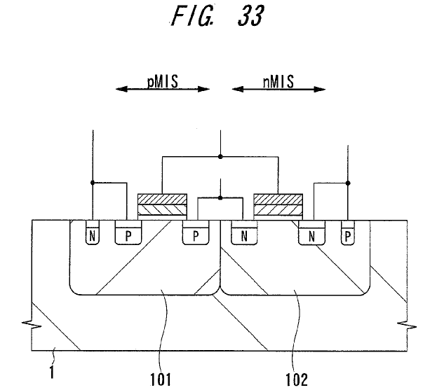

A discharge countermeasure circuit of the twelfth example according to the seventh embodiment will be described. A schematic cross-sectional view of the discharge countermeasure circuit of the twelfth example is shown in FIG. 32. While the discharge countermeasure circuit of the twelfth example has a configuration similar to that of the abovedescribed discharge countermeasure circuit of the eleventh example, a difference of the discharge countermeasure circuit of the twelfth example from the abovedescribed discharge countermeasure circuit of the eleventh example lies in that the gate electrode of the nMIS 285n and the p-type semiconductor region 286 formed in the shallow p-type well 282 are connected by a wiring 292 formed in a step after a step where breakdown of the gate insulating film may occur due to plasma discharge. It is desirable that the wiring connection is performed by wirings of the uppermost layer. By fixing the gate electrode of the nMIS 285n to the ground potential GND and always putting the nMIS 285n in OFF state during a circuit operation of the semiconductor device in this manner, the nMIS 285n is prevented from exerting adverse effect such as leakage to another circuit.

A discharge countermeasure circuit of the thirteenth example according to the seventh embodiment will be described. While the discharge countermeasure circuits of the abovedescribed first example to twelfth example are each a countermeasure circuit for handling charging occurring in the deep n-type well 200, a countermeasure circuit for handling charging occurring in the deep p-type well can also be similarly formed by reversing polarity. That is, in the discharge countermeasure circuits of the abovedescribed first example to twelfth example, the shallow n-type well 281 and the shallow p-type well 282 are formed in different regions from each other in the deep n-type well 200, and the nMIS 285n solving a potential difference between-wells is formed in the shallow p-type well 282, so that the shallow n-type well 281 is used as a well for charging countermeasure, while a shallow p-type well and a shallow n-type well are formed in different regions from each other in the deep n-type well and a pMIS for cancelling potential difference between wells is formed in the shallow n-type well so that the shallow p-type well is used as a well for charging countermeasure in the charge countermeasure circuit of the thirteenth example.

Note that, while there has been described that “inverter circuits configured by a pMIS (not shown) formed in a shallow n-type well 101 and an nMIS (not shown) formed in the shallow p-type well 102 which are formed in the substrate 1” in the description about the first failure generation mechanism described above, the inverter circuit is like the following, specifically.

FIG. 33 shows a cross-sectional view of the abovedescribed inverter circuit. The shallow n-type well 101 and the shallow p-type well 102 are formed in different regions from each other in the substrate 1, and further, a pMIS is formed in the shallow n-type well 101, and an nMIS is formed in the shallow p-type well 102. These pMIS and nMIS form an inverter circuit, and a gate electrode of the pMIS and a gate electrode of the nMIS are in a floating state as connected with each other.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be applied to a technique effectively applied to a semiconductor device having a triple well structure to be adopted in, for example, universal SOC products.

What is claimed is:

1. A semiconductor device comprising an inverter circuit that includes:
a substrate of a first conductivity type;
a deep-well of a second conductivity type different from the first conductivity type formed in the substrate;
a first shallow well of the first conductivity type and a second shallow well of the second conductivity type formed in different regions from each other in the deep-well;
a second field effect transistor of the second conductivity type formed in the first shallow well; and
a first field effect transistor of the first conductivity type and formed in the second shallow well, wherein
a first gate electrode of the first field effect transistor and a second gate electrode of the second field effect transistor are directly or indirectly connected to: the substrate; a portion having a substrate potential; the deep-well; a shallow well of the first conductivity type; a shallow well of the second conductivity type; or a predetermined portion regarding circuit operations by using a first wiring, and the first shallow well is directly or indirectly connected to the substrate or a portion having a substrate potential by using a second wiring included in a layer lower than the first wiring, and wherein
a number of connection holes formed in an insulating film just above the first wiring is less than a number of connection holes formed in an insulating film just above a wiring of a layer lower than the first wiring.

2. The semiconductor device according to claim 1, wherein the first wiring is a wiring of an uppermost layer.

3. The semiconductor device according to claim 1, wherein the second wiring is a wiring of a first layer.

4. The semiconductor device according to claim 1, wherein the deep-well is not connected to the substrate.

5. The semiconductor device according to claim 1, wherein the first gate electrode of the first field effect transistor and the second gate electrode of the second field effect transistor are connected by a conductive material of a same layer configuring both the first and second gate electrodes.

6. The semiconductor device according to claim 1, wherein the first gate electrode of the first field effect transistor is formed of a stacked film of a silicon film of the first conductivity type and a silicide layer; the second gate electrode of the second field effect transistor is formed of a stacked layer of a silicon film of the second conductivity type and a silicide layer of the same layer as the silicide layer of the first field effect transistor; and the first gate electrode of the first field effect transistor and the second gate electrode of the second field effect transistor are connected to each other by the silicide layer.

7. The semiconductor device according to claim 1, wherein the inverter circuit does not contribute to circuit operations.

8. The semiconductor device according to claim 1, wherein charges which have flowed into the deep-well or the second shallow well are discharged to the substrate or a portion having a substrate potential via the first shallow well and the second wiring.

9. A semiconductor device comprising an inverter circuit that includes:
a substrate of a first conductivity type;
a deep-well of a second conductivity type different from the first conductivity type and formed in the substrate;
a first shallow well of the first conductivity type and formed in a region other than the deep-well;
a second shallow well of the second conductivity type and formed in the deep-well;
a second field effect transistor of the second conductivity type and formed in the first shallow well; and
a first field effect transistor of the first conductivity type and formed in the second shallow well, wherein a first gate electrode of the first field effect transistor and a second gate electrode of the second field effect transistor are directly or indirectly connected to: the substrate; a portion having a substrate potential; the deep-well; a shallow well of the first conductivity type; a shallow well of the second conductivity type; or a predetermined portion regarding circuit operations by using a first wiring, and wherein
a number of connection holes formed in an insulating film just above the first wiring is less than a number of connection holes formed in an insulating film just above a wiring of a layer lower than the first wiring.

10. The semiconductor device according to claim 9, wherein the first wiring is a wiring of an uppermost layer.

11. The semiconductor device according to claim 9, wherein the deep-well is not connected to the substrate.

12. The semiconductor device according to claim 9, wherein the first gate electrode of the first field effect transistor and the second gate electrode of the second field effect transistor are connected by a conductive material of a same layer configuring both the first and second gate electrodes.

13. The semiconductor device according to claim 9, wherein the first gate electrode of the first field effect transistor is formed of a stacked film of a silicon film of the first conductivity type and a silicide layer; the second gate electrode of the second field effect transistor is formed of a stacked layer of a silicon film of the second conductivity type and a silicide layer of the same layer as the silicide layer of the first field effect transistor; and the first gate electrode of the first field effect transistor and the second gate electrode of the second field effect transistor are connected to each other by the silicide layer.

14. The semiconductor device according to claim 9, wherein the inverter circuit does not contribute to circuit operations.

15. The semiconductor device according to claim 9, wherein charges which have flowed into the deep-well or the second shallow well are discharged to the substrate via the first shallow well.

16. A semiconductor device comprising an inverter circuit that includes:
a substrate of a first conductivity type;
a deep-well of a second conductivity type different from the first conductivity type and formed in the substrate;
a second shallow well of the second conductivity type and formed in the deep-well;
a first shallow well of the first conductivity type and formed in a region other than the second shallow well and not connected to either of one or more portions having a substrate potential, the deep-well, or one or more shallow wells of the second conductivity type;
a second field effect transistor of the second conductivity type and formed in the first shallow well; and
a first field effect transistor of the first conductivity type and formed in the second shallow well, wherein
a first gate electrode of the first field effect transistor and a second gate electrode of the second field effect transistor are directly or indirectly connected to: the substrate; the one or more portions having a substrate potential; the deep-well; a shallow well of the first conductivity type; the one or more shallow wells of the second conductivity type; or a predetermined portion regarded by circuit operations by using a first wiring, and wherein
a number of connection holes formed in an insulating film just above the first wiring is less than a number of connection holes formed in an insulating film just above a wiring of a layer lower than the first wiring.

17. The semiconductor device according to claim 16, wherein the first wiring is a wiring of an uppermost layer.

18. The semiconductor device according to claim 16, wherein the first gate electrode of the first field effect transistor and the second gate electrode of the second field effect transistor are connected by a conductive material of a same layer configuring both the first and second gate electrodes.

19. The semiconductor device according to claim 16, wherein the first gate electrode of the first field effect transistor is formed of a stacked film of a silicon film of the first conductivity type and a silicide layer; the second gate electrode of the second field effect transistor is formed of a stacked layer of a silicon film of the second conductivity type and a silicide layer of the same layer as the silicide layer of the first field effect transistor; and the first gate electrode of the first field effect transistor and the second gate electrode of the second field effect transistor are connected to each other by the silicide layer.

20. The semiconductor device according to claim 16, wherein the inverter circuit does not contribute to circuit operations.

21. The semiconductor device according to claim 16, wherein charges which have flowed into the deep-well or the second shallow well are discharged to the substrate via the second shallow well and the deep-well.

22. A semiconductor device comprising an inverter circuit that includes:
a substrate of a first conductivity type;
a deep-well of a second conductivity type different from the first conductivity type and formed in the substrate;
a first shallow well of the first conductivity type and a second shallow well of the second conductivity type formed in different regions from each other in the deep-well;
a second field effect transistor of the second conductivity type and formed in the first shallow well; and
a first field effect transistor of the first conductivity type and formed in the second shallow well, wherein
a gate electrode of the first field effect transistor and a gate electrode of the second field effect transistor are directly or indirectly connected to: the substrate; a portion having a substrate potential; or a portion having a power-supply voltage by using a first wiring, and wherein
a number of connection holes formed in an insulating film just above the first wiring is less than a number of connection holes formed in an insulating film just above a wiring of a layer lower than the first wiring.

23. A semiconductor device comprising:
a substrate of a first conductivity type;
a deep-well of a second conductivity type different from the first conductivity type and formed in the substrate; and
a first shallow well of the first conductivity type and a second shallow well of the second conductivity type formed in the deep-well, wherein
at least one of the deep-well, the first shallow well, and the second shallow well is directly or indirectly connected to the substrate or a portion having a substrate potential by using a first wiring, and
a number of connection holes formed in an insulating film just above the first wiring is less than a number of connection holes formed in an insulating film just above a wiring of a layer lower than the first wiring.

24. The semiconductor device according to claim 22, wherein the first wiring is a wiring of an uppermost layer.

25. A semiconductor device comprising:
a substrate of a first conductivity type;
a deep-well of a second conductivity type different from the first conductivity type and formed in the substrate; and
a first shallow well of the first conductivity type and a second shallow well of the second conductivity type formed in different regions from each other in the deep-well, wherein
a portion in the second shallow well and the substrate or a portion in a well having a substrate potential are directly or indirectly connected to each other by a first wiring, and
the number of connection holes formed in an insulating film just above the first wiring is less than the number of connection holes formed in an insulating film just above a wiring of a layer lower than the first wiring.

26. A semiconductor device comprising:
a substrate of a first conductivity type;
a deep-well of a second conductivity type different from the first conductivity type and formed in the substrate;
a second shallow well of the second conductivity type and formed in the deep-well; and
a first shallow well of the first conductivity type and formed in a region other than the second shallow well in the deep-well, and not connected to one or more wells having a substrate potential, the deep-well, or one or more shallow wells of the second conductivity type, wherein
a portion in the first shallow well and the substrate, a portion in the one or more wells having a substrate potential, or a portion in the one or more shallow wells of the second conductivity type are directly or indirectly connected to each other by a first wiring, and
the number of connection holes formed in an insulating film just above the first wiring is less than the number of connection holes formed in an insulating film just above a wiring of a layer lower than the first wiring.

27. The semiconductor device according to claim 25, wherein the first wiring is a wiring of an uppermost layer.

28. A semiconductor device comprising
a substrate of a first conductivity type;
a deep-well of a second conductivity type different from the first conductivity type and formed in the substrate;
a first shallow well of the first conductivity type and a second shallow well of the second conductivity type formed in different regions from each other in the deep-well; and
a field effect transistor of the second conductivity type formed in the first shallow well, wherein
a drain of the field effect transistor is connected to the second shallow well, the first shallow well is connected to a ground potential, and the gate electrode of the field effect transistor is directly or indirectly connected to the second shallow well, so that the field effect transistor is turned ON or OFF according to an amount of charges of the second shallow well.

29. The semiconductor device according to claim 28, wherein the drain is connected to the field effect transistor and the second shallow well by using a wiring of a first layer, and the first shallow well is connected to a ground potential.

30. The semiconductor device according to claim 28 further comprising a first semiconductor region of the first conductivity type in the second shallow well, wherein the first semiconductor region is electrically connected to the gate electrode of the field effect transistor by using a second wiring.

31. The semiconductor device according to claim 28, further comprising a first semiconductor region of the first conductivity type in the second shallow well, wherein the first semiconductor region is electrically connected to the gate electrode of the field effect transistor by using a second wiring, and the first semiconductor region is electrically connected to a ground potential using a first wiring of a layer upper than the second wiring.

32. The semiconductor device according to claim 28 further comprising a first semiconductor region of the first conductivity type in the second shallow well, wherein the first semiconductor region and the gate electrode of the field effect transistor are connected by a plug electrode buried in a connection hole formed so as to span the first semiconductor region and the gate electrode of the field effect transistor.

33. The semiconductor device according to claim 28 further comprising a capacitor element that includes: the second shallow well; an insulating film formed on the second shallow well; and a gate formed on the insulating film, wherein a gate of the capacitor element is electrically connected to the gate electrode of the field effect transistor by using a second wiring.

34. The semiconductor device according to claim 28 further comprising a capacitor element that includes: the second shallow well; an insulating film formed on the second shallow well; and a gate formed on the insulating film, wherein a gate of the capacitor element is electrically connected to the gate electrode of the field effect transistor by using a second wiring, wherein the gate of the capacitor element is electrically connected to a ground potential by using a first wiring of a layer upper than the second wiring.

35. The semiconductor device according to claim 28 further comprising a capacitor element that includes: the second shallow well; an insulating film formed on the second shallow well; and a gate formed on the insulating film, wherein a gate of the capacitor element is electrically connected to the gate electrode of the field effect transistor by using a second wiring, wherein
a gate capacitance of the capacitor element is larger than a gate capacitance of the field effect transistor.

36. The semiconductor device according to claim 28 further comprising a capacitor element that includes: the second shallow well; an insulating film formed on the second shallow well; and a gate formed on the insulating film, wherein a gate of the capacitor element is electrically connected to the gate electrode of the field effect transistor by using a second wiring, wherein
a capacitance obtained by connecting a gate capacitance of the capacitor element and a capacitance of a depletion layer formed in the second shallow well below the gate of the capacitor element in series is larger than a gate capacitance of the field effect transistor.

37. The semiconductor device according to claim 28 further comprising a capacitor element that includes: the second shallow well; an insulating film formed on the second shallow well; and a gate formed on the insulating film, wherein a gate of the capacitor element is electrically connected to the gate electrode of the field effect transistor by using a second wiring, wherein
an inversion layer is formed in the second shallow well below the gate of the capacitor element, and a gate capacitance of the capacitor element is larger than a gate capacitance of the field effect transistor.

38. The semiconductor device according to claim 28 further comprising a first semiconductor region of the first conductivity type in the second shallow well, wherein the first semiconductor region is electrically connected to the gate electrode of the field effect transistor using a second wiring, and
a junction capacitance of the first semiconductor region and the second shallow well is larger than a gate capacitance of the field effect transistor.

39. A semiconductor device comprising:
a substrate of a first conductivity type;
a deep-well of a second conductivity type different from the first conductivity type and formed in the substrate;
a first shallow well of the first conductivity type and a second shallow well of the second conductivity type formed in different regions from each other in the deep-well; and
a field effect transistor of the second conductivity type formed in the first shallow well, wherein
a drain of the field effect transistor is connected to the second shallow well, the first shallow well is connected to a ground potential, and a gate electrode of the field effect transistor is connected to a wiring put in a floating state, so that the field effect transistor is turned ON or OFF according to an intermediate potential of the wiring put in the floating state.

40. The semiconductor device according to claim 39, wherein the drain of the field effect transistor is connected to the second shallow well by using a wiring of the first layer, and the first shallow well is connected to a ground potential.

41. The semiconductor device according to claim 39, wherein a potential that makes the field effect transistor turned OFF is applied to the wiring put in the floating state by a wiring of an layer upper than the wiring put in the floating state.

42. The semiconductor device according to claim 39, wherein the gate electrode of the field effect transistor is electrically connected to a ground potential by using a third wiring of a layer upper than the wiring put in the floating state.

43. The semiconductor device according to claim 31, wherein the first wiring is a wiring of an uppermost layer.

44. The semiconductor device according to claim 30, wherein the second wiring is a wiring of a first layer.

45. The semiconductor device according to claim 42, wherein the third wiring is a wiring of an uppermost layer.
